(19) United States
(12) Patent Application Publication
(10) Pub. No.: US 2026/0173516 A1
(43) Pub. Date: Jun. 18, 2026

(54) ISOLATION STRUCTURE FOR STACKED MULTI-GATE DEVICE

(71) Applicant: Taiwan Semiconductor Manufacturing Company, Ltd., Hsin-Chu (TW)

(72) Inventors: Zhi-Chang Lin, Hsinchu County (TW); Chia-Jung Tsai, Hsinchu City (TW)

(21) Appl. No.: 19/218,265

(22) Filed: May 24, 2025

Related U.S. Application Data
(60) Provisional application No. 63/735,211, filed on Dec. 17, 2024.

(51) Int. Cl. H10D 84/85; H01L 21/762; H10D 30/00; H10D 30/01; H10D 30/43; H10D 62/10; H10D 64/01

(52) U.S. Cl. CPC H10D 84/851; H10D 30/0191; H10D 30/503; H10D 62/102; H10D 62/121; H10D 64/017; H10W 10/0145; H10W 10/17; H10D 30/014; H10D 30/43

(57) ABSTRACT

Semiconductor structures and methods of forming the same are provided. An exemplary method includes receiving a workpiece that includes a fin-shaped structure and a dummy gate stack disposed over the fin-shaped structure. The fin-shaped structure includes a fin-shaped base, a bottom semiconductor stack, a middle dielectric layer over the bottom semiconductor stack, and a top semiconductor stack. Each of the top and bottom semiconductor stacks including channel layers interleaved by sacrificial layers. The method further includes recessing a portion of the dummy gate stack to form a trench to expose the fin-shaped structure, removing the sacrificial layers in the top and bottom semiconductor stacks from the trench, removing the channel layers in the top and bottom semiconductor stacks from the trench, and depositing a dielectric feature in the trench. The dielectric feature wraps around the middle dielectric layer.

### PRIORITY DATA

This application claims priority to U.S. Provisional Application No. 63/735,211, filed Dec. 17, 2024, which is herein incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. The channel region of a GAA transistor may be formed from nanowires, nanosheets, or other suitable nanostructures. Due to the shape of the channel region, a GAA transistor may also be referred to as a nanosheet transistor or a nanowire transistor.

As the semiconductor industry advances to achieve higher device density, performance, and cost efficiency, fabrication and design challenges have driven the adoption of stacked device structures. One such configuration is the complementary field-effect transistor (C-FET), in which an n-type multi-gate transistor and a p-type multi-gate transistor are stacked vertically, one over the other. While existing isolation structures and fabrication techniques thereof for the C-FET are generally adequate for their intended purpose, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a perspective view of a semiconductor device including a vertical C-FET, according to one or more aspects of the present disclosure.

FIG. 2 illustrates a flow chart of a method for forming a semiconductor device including vertical C-FETs, according to one or more aspects of the present disclosure.

FIGS. 3A, 3B, 4, 5, 6, 7, 8, 9, 10, 11, 12, 13A, 13B, 14A, 14B, 15A, 15B, 16A, 16B, 17A, 17B, 18A, 18B, 19A, 19B, 20A, 20B, 21A, 21B, 22A, 22B, 23A, 23B, 24A, 24B, 25A, 25B, 26A, 26B, 27A, 27B, 28A, and 28B illustrate fragmentary cross-sectional views of a workpiece during various fabrication stages in the method of FIG. 2, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a bottom multi-gate device and a top multi-gate device stacked over the bottom multi-gate device. When the bottom multi-gate device and the top multi-gate device are transistors of different conductivity types, the stacked multi-gate device may be a complementary field effect transistor (C-FET). The multi-gate devices in a C-FET may be FinFETs or GAA transistors. A middle dielectric layer, interposed between the stacked transistors of a C-FET, electrically isolates the n-type and p-type transistors, preventing current leakage and minimizing cross-talk. To maintain continued scaling and increased density in advanced technology nodes, a cut-on-poly-oxide-definition-edge (CPODE) process may be used to form an isolation structure (referred to as a CPODE structure or CPODE feature) that facilitates further reduction of the contacted poly pitch (CPP) (or “gate pitch”). However, the presence of the middle dielectric layer introduces challenges in forming a CPODE feature in C-FETs. For instance, the CPODE feature may be formed by filling a CPODE trench, which is created by selectively removing a portion of a dummy gate structure and the underneath stacked active regions that are inserted with the middle dielectric layer. The removal of dielectric material from the middle dielectric layer, along with semiconductor materials from the stacked active regions, generally requires high-bias etching, which may cause damage to adjacent dielectric features (e.g., gate spacers and inner spacers) and other semiconductor features.

The present disclosure provides a method for forming a CPODE feature in C-FETs without substantially removing the middle dielectric layer. This approach enables the use of mild etching to form the CPODE trench, reducing the risk of damage to adjacent dielectric features and semiconductor features. The dielectric material filling the CPODE trench wraps around the middle dielectric layer, integrating it as part of the formed CPODE feature.

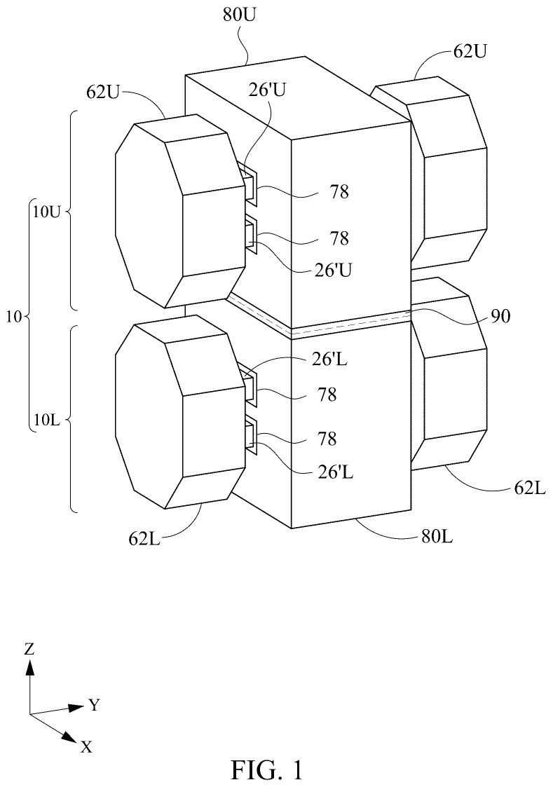

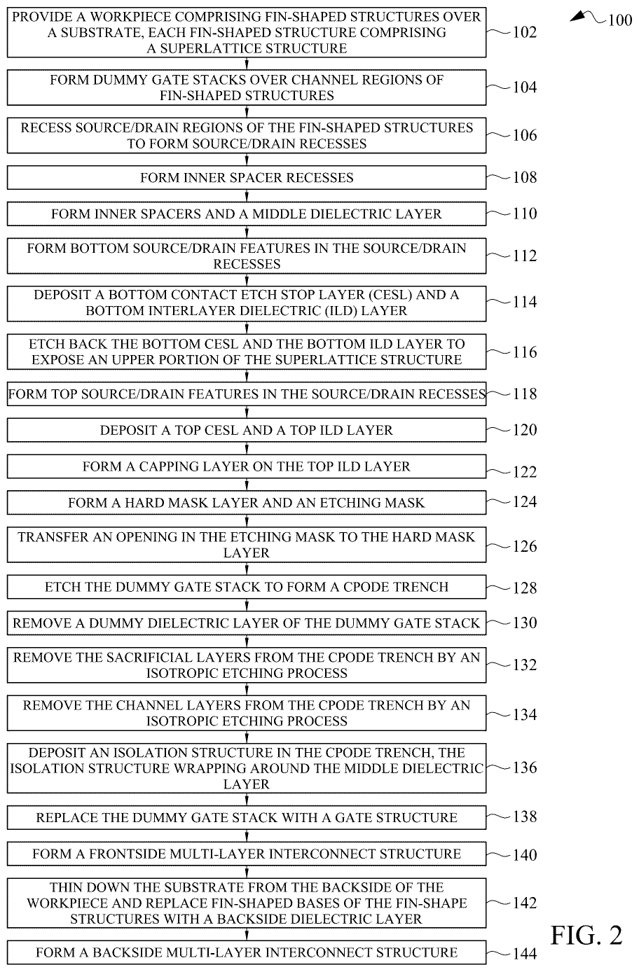

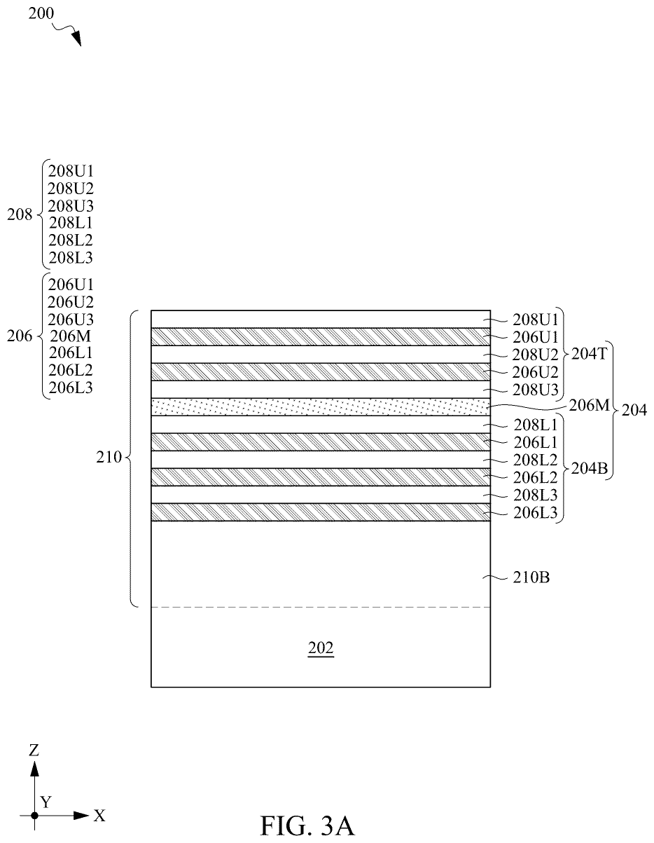

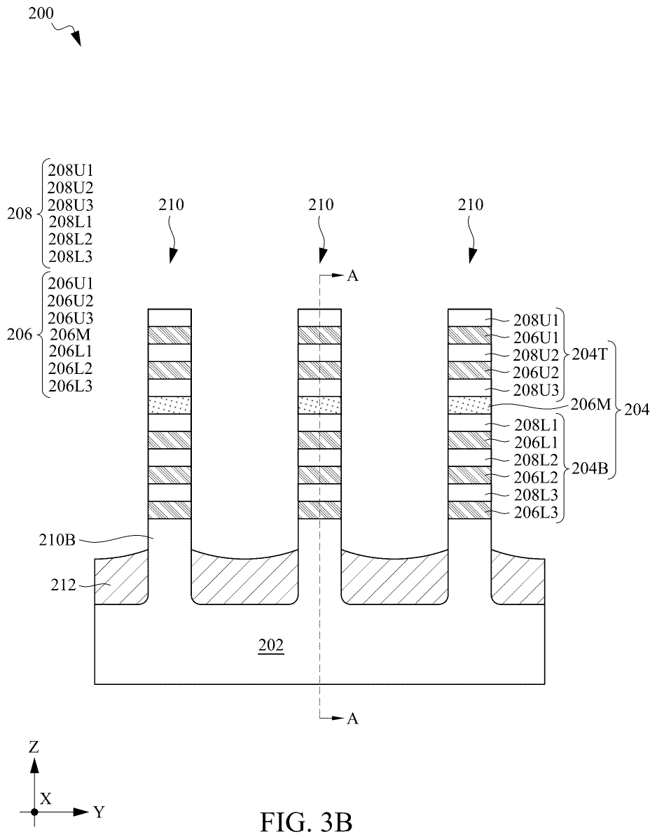

The various aspects of the present disclosure will now be described in more detail with reference to the figures. In that regard, FIG. 1 illustrates a perspective view of a semiconductor device including a C-FET, according to one or more aspects of the present disclosure. FIG. 2 illustrates a flow chart of a method 100 for forming a workpiece 200 including C-FETs, according to one or more aspects of the present disclosure. Method 100 is described below in conjunction with FIGS. 3A-23B, which are fragmentary cross-sectional views of the workpiece 200 at different stages of fabrication according to embodiments of method 100. Method 100 is merely an example and is not intended to limit the present disclosure to what is explicitly illustrated therein. Additional steps may be provided before, during and after method 100, and some steps described can be replaced, eliminated, or moved around for additional embodiments of the method. Not all steps are described herein in detail for reasons of simplicity. Because the workpiece 200 will be fabricated into a semiconductor device upon conclusion of the fabrication processes, the workpiece 200 may be referred to as the semiconductor device 200 or semiconductor structure 200 as the context requires. Additionally, throughout the present application and across different embodiments, like reference numerals denote like features with similar structures and compositions, unless otherwise excepted. For avoidance of doubts, the X, Y and Z directions in the figures are perpendicular to one another and are used consistently.

FIG. 1 depicts an exemplary semiconductor device (e.g., C-FET) 10. The semiconductor device 10 includes a lower device 10L (e.g., a p-type transistor) and an upper device 10U (e.g., an n-type transistor) over the lower device 10L. The lower device 10L includes channel layer 26′L wrapped around by a bottom gate structure. The bottom gate structure includes a gate dielectric layer 78 and a gate electrode layer 80L. The lower device 10L also includes source/drain features (e.g., p-type epitaxial source/drain features) 62L coupled to the channel layers 26′L and adjacent the bottom gate structure.

The upper device 10U includes channel layer 26′U wrapped around by an upper gate structure. The upper gate structure includes the gate dielectric layer 78 and a gate electrode layer 80U. The upper device 10U also includes source/drain features (e.g., n-type epitaxial source/drain features) 62U coupled to the channel layers 26′U and adjacent the upper gate structure. An isolation layer 90 is disposed between the upper device 10U and the lower device 10L to electrically insulate the upper gate structure of the upper device 10U from the bottom gate structure of the lower device 10L. Since the isolation layer 90 is positioned vertically in the middle of the semiconductor device 10, it is also referred to as the middle dielectric layer 90. The configurations of the elements in the semiconductor device 10 described above are given for illustrative purposes and can be modified depending on the actual implementations. It is understood that some features are omitted in this figure for reason of simplicity.

Referring now to FIGS. 2 and 3A-3B, method 100 includes a block 102 where a workpiece 200 is received. FIG. 3A depicts a cross-sectional view of the workpiece 200 in the X-Z plane, which is taken along cutline A-A shown in FIG. 3B, and FIG. 3B depicts a cross-sectional view of the workpiece 200 in the Y-Z plane. The workpiece 200 includes a substrate 202. In one embodiment, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202. For ease of reference, the substrate 202 and structures formed thereon during the method 100 may be referred to as a workpiece 200.

The workpiece 200 also includes fin-shaped structures 210 formed over the substrate 202. In the present embodiments, the fin-shaped structure 210 is formed from a superlattice structure 204 and a top portion of the substrate 202. The superlattice structure 204 may be deposited over the substrate 202 using an epitaxy process. Suitable epitaxy processes include vapor-phase epitaxy (VPE), ultra-high vacuum chemical vapor deposition (UHV-CVD), molecular beam epitaxy (MBE), and/or other suitable processes. The superlattice structure 204 includes a number of channel layers 208 interleaved by a number of sacrificial layers 206. The sacrificial layers 206 and the channel layers 208 are deposited alternatingly, one-after-another, to form the superlattice structure 204. The channel layers 208 and the sacrificial layers 206 may have different semiconductor compositions. In some implementations, the channel layers 208 are formed of silicon (Si) and sacrificial layers 206 are formed of silicon germanium (SiGe). In these implementations, the additional germanium content in the sacrificial layers 206 allow selective removal or recess of the sacrificial layers 206 without inducing substantial damages to the channel layers 208.

For ease of references, the superlattice structure 204 may be vertically divided into a bottom portion 204B, a middle sacrificial layer 206M on the bottom portion 204B, and a top portion 204T on the middle sacrificial layer 206M. In this depicted example, the bottom portion 204B of the superlattice structure 204 includes channel layers 208L1, 208L2 and 208L3 interleaved by sacrificial layers 206L1, 206L2, and 206L3. The top portion 204T of the superlattice structure 204 includes channel layers 208U1, 208U2 and 208U3 interleaved by sacrificial layers 206U1 and 206U2. The channel layers 208L1, 208L2, 208L3, 208U1, 208U2, and 208U3 will provide nanostructures as channel regions for the C-FET 10. In some embodiments, the channel layers 208U1-208U2, and the channel layers 208L2-208L3 will provide nanostructures as channel regions for a top GAA transistor and a bottom GAA transistor in the C-FET 10, respectively. The nanostructures in which the channel regions reside are also referred to as channel members. The term “channel member” as used herein designates any material portion for channel(s) in a transistor with nanoscale dimensions, and having an elongate shape, regardless of the cross-sectional shape of this portion. A germanium content of the middle sacrificial layer 206M may be different from the germanium content of other sacrificial layers (e.g., sacrificial layers 206U1-206U3, sacrificial layers 206L1-206L3) of the top portion 204T and bottom portion 204B. In some embodiments, a germanium content of the middle sacrificial layer 206M may be greater than a germanium content of the other sacrificial layers 206U1-206U3 and 206L1-206L3 such that the entirety of the middle sacrificial layer 206M may be selectively removed during the formation of inner spacer recesses. In furtherance of some embodiments, a germanium concentration in molar ratio of the sacrificial layers 206U1-206U3 and 206L1-206L3 may range from about 10% to about 50%, and a germanium concentration in molar ratio of the middle sacrificial layer 206M may range from about 20% to about 80%.

It is noted that the superlattice structure 204 in FIGS. 3A-3B includes six (6) layers of the channel layers 208 interleaved by six (6) layers of sacrificial layers 206, which is for illustrative purposes only and not intended to be limiting beyond what is specifically recited in the claims. It can be appreciated that any number of the channel layers 208 can be included in the superlattice structure 204 and distributed between the bottom portion 204B and the top portion 204T. The number of layers depends on the desired number of channels members for the top GAA transistor and the bottom GAA transistor. In some embodiments, the number of the channel layers 208 in the superlattice structure 204 may be between 4 and 10. The thicknesses of the channel layers 208 and the sacrificial layers 206 may be selected based on device performance considerations of the bottom GAA transistor, the top GAA transistor, and the C-FET as a whole.

After forming the superlattice structure 204, the superlattice structure 204 and a top portion of the substrate 202 are then patterned to form the fin-shaped structures 210. For patterning purposes, a hard mask layer may be deposited over the superlattice structure 204. The hard mask layer may be a single layer or a multilayer. In one example, the hard mask layer includes a silicon oxide layer and a silicon nitride layer over the silicon oxide layer. As shown in FIGS. 3A-3B, each fin-shaped structure 210 extends vertically along the Z direction from the substrate 202 and extends lengthwise along the X direction. The fin-shaped structures 210 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the superlattice structure 204 and a top portion of the substrate 202 to form the fin-shaped structures 210, including fin-shaped bases 210B from the patterned top portion of the substrate 202. The horizontal dotted line in FIG. 3A and subsequent figures indicates the position of the bottom of the fin-shaped structures 210, which also corresponds to the recessed top surface of the substrate 202.

Referring to FIG. 3B, the workpiece 200 also includes an isolation feature 212 formed around the fin-shaped structures 210 to separate two adjacent fin-shaped structures 210. The isolation feature 212 may also be referred to as a shallow trench isolation (STI) feature 212. In an example process, a dielectric material for the isolation feature 212 is deposited over the workpiece 200, including the fin-shaped structure 210, using CVD, subatmospheric CVD (SACVD), flowable CVD, spin-on coating, and/or other suitable process. Then the deposited dielectric material is planarized and recessed to form the isolation feature 212. The fin-shaped structures 210 rise above the isolation feature 212. In the illustrated embodiment, the top surface of the isolation feature 212 intersects opposing sidewalls of the fin-shaped bases 210B. The top surface of the isolation feature 212 may exhibit a dishing profile, such that the top surface is non-planar and bending downward, due to etchant loading effect during the recessing process. The dielectric material for the isolation feature 212 may include silicon oxide, silicon oxynitride, fluorine-doped silicate glass (FSG), a low-k dielectric, combinations thereof, and/or other suitable materials. A dielectric constant of the dielectric material for the isolation feature 212 may range from about 3 to about 5 in some embodiments.

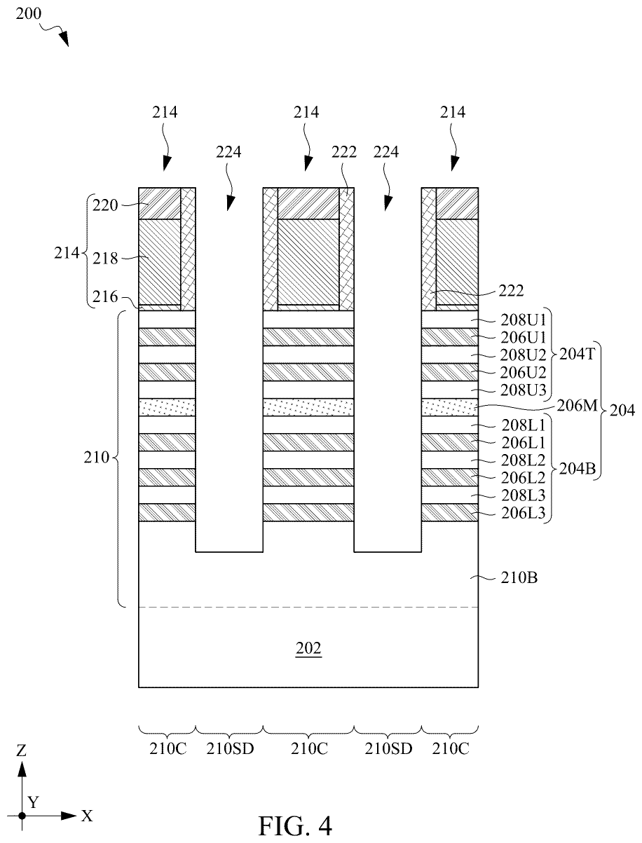

Referring to FIGS. 2 and 4, method 100 includes a block 104 where dummy gate stacks (also referred to as dummy gate structures) 214 are formed over channel regions 210C of the fin-shaped structure 210. In some embodiments, a gate replacement process (or gate-last process) is adopted where the dummy gate stacks 214 serve as placeholder for functional gate structures. Other processes and configurations are possible. To form the dummy gate stacks 214, a dummy dielectric layer 216, a dummy gate electrode layer 218, and a gate-top hard mask layer 220 are deposited over the workpiece 200. The deposition of these layers may include use of low-pressure CVD (LPCVD), CVD, plasma-enhanced CVD (PECVD), physical vapor deposition (PVD), atomic layer deposition (ALD), thermal oxidation, e-beam evaporation, other suitable deposition techniques, and/or combinations thereof. The dummy dielectric layer 216 may include silicon oxide, the dummy gate electrode layer 218 may include polysilicon, and the gate-top hard mask layer 220 may be a multi-layer that includes silicon oxide and silicon nitride. Using photolithography and etching processes, the gate-top hard mask layer 220 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching, wet etching, and/or other etching methods. Like the fin-shaped structures 210, the dummy gate stacks 214 may also be patterned using double-patterning or multiple-patterning techniques. Thereafter, using the patterned gate-top hard mask 220 as an etch mask, the dummy dielectric layer 216 and the dummy gate electrode layer 218 are etched to form the dummy gate stacks 214. Each dummy gate stack 214 extends lengthwise along the Y direction, wrapping over the fin-shaped structure 210 and landing on the isolation feature 212. The portion of the fin-shaped structure 210 underlying each dummy gate stack 214 defines a channel region 210C. Each channel region 210C and its corresponding dummy gate stack 214 also define source/drain regions 210SD that are not vertically overlapped by the dummy gate stack 214. The channel region 210C is disposed between two source/drain regions 210SD along the X direction. Source/drain region(s) may refer to a source region for forming a source or a drain region for forming a drain, individually or collectively dependent upon the context.

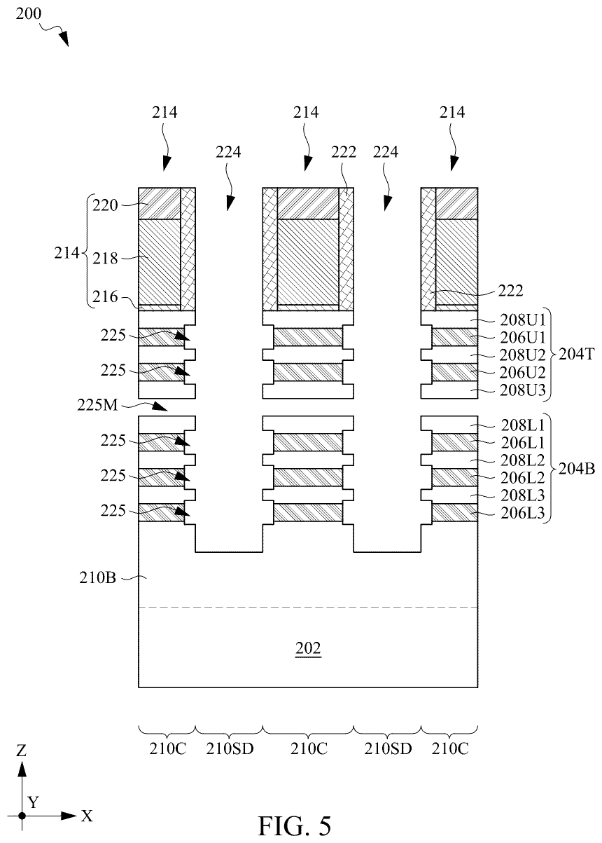

Still referring to FIGS. 2 and 4, method 100 includes a block 106 where source/drain regions 210SD of the fin-shaped structure 210 are recessed to form source/drain trenches (also referred to as source/drain recesses) 224. Operations at block 106 may include formation of gate spacers 222 over the sidewalls of the dummy gate stacks 214 before the source/drain regions 210SD are recessed. In some embodiments, the formation of the gate spacers 222 includes deposition of one or more dielectric layers over the workpiece 200. In an example process, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. After the deposition of the gate spacers 222, an anisotropic etch process is performed to the workpiece 200 to form the source/drain trenches 224. The etch process at block 106 may be a dry etch process or other suitable etch process. An example dry etch process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As shown in FIG. 5, sidewalls of the sacrificial layers 206 and the channel layers 208 in the channel regions 210C are exposed in the source/drain trenches 224.

Referring to FIGS. 2 and 5, method 100 includes a block 108 where inner spacer recesses 225 are formed. An etching process may be performed to selectively and partially recess the sacrificial layers 206 exposed in the source/drain trenches 224 to form inner spacer recesses 225. In some embodiments, the etching process may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include use of hydrogen fluoride (HF) or ammonium hydroxide (NH₄OH). In the illustrated embodiment, a germanium content of the middle sacrificial layer 206M is greater than a germanium content of the sacrificial layers 206U1-206U3 and 206L1-206L3, and an etchant of the etching process etches the middle sacrificial layer 206M at a rate higher than it etches the other sacrificial layers. As a result, the inner spacer recesses 225 are formed by partially laterally recessing the sacrificial layers 206U1-206U3 and 206L1-206L3, while the entirety of the middle sacrificial layer 206M is removed during the formation of inner spacer recesses, leaving a gap 225M extending throughout the fin-shape structure 210 and separating the top portion 204T and the bottom portion 204B. Also in the illustrated embodiment, the end portions of the channel layers 208 may experience etching loss, particularly in the vertical direction, due to limited etching contrast. As a result, the thickness of the channel layers 208 at the end portions may be smaller than at the middle portions, and the vertical height of the inner spacer recesses 225 may exceed the thickness of the sacrificial layers 206. Additionally, the two channel layers 208L1 and 208U3, which sandwich the gap 225M, may undergo vertical recessing at their top and bottom surfaces, respectively, where they directly face the gap 225M. Consequently, the gap 225M may expand in the vertical direction, becoming thicker than the original thickness of the middle sacrificial layer 206M. Thus, the thickness of channel layers 208L1 and 208U3 may be reduced compared to other channel layers 208L2-208L3 and 208U1-208U2.

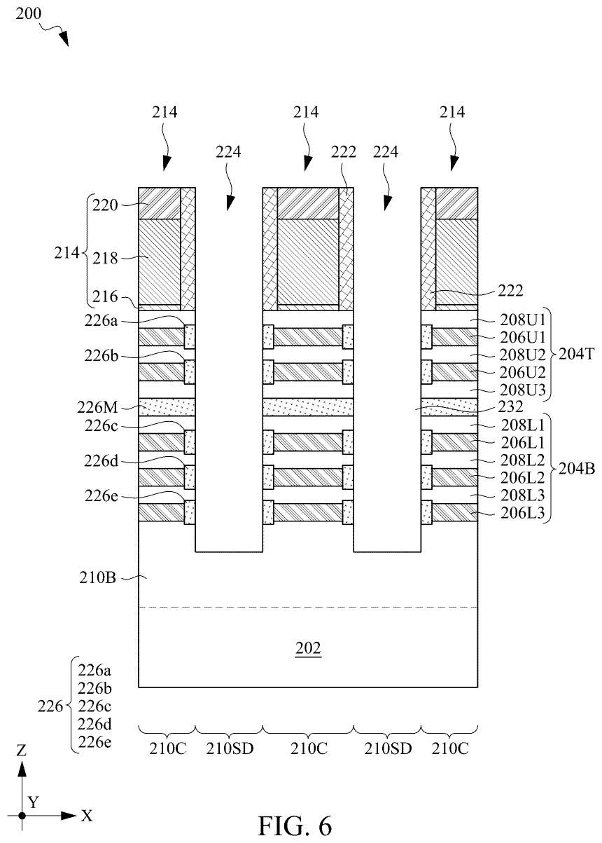

Referring to FIGS. 2 and 6, method 100 includes a block 110 where inner spacers 226 are formed. After the formation of the inner spacer recesses 225, an inner spacer material layer is deposited over the workpiece 200 filling the inner spacer recesses 225. Additionally, the inner spacer material layer is also deposited in the gap 225M, which is the space left behind by selective removal of the middle sacrificial layer 206M. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess portions of the inner spacer material layer over the dummy gate stack 214, the gate spacers 222, and sidewalls of the channel layers 208, thereby forming the inner spacers 226 and the middle dielectric layer 226M. In the present embodiments, the inner spacers 226 includes inner spacers 226a and 226b disposed over the middle dielectric layer 226M and inner spacers 226c, 226d, and 226e disposed under the middle dielectric layer 226M. Each of the inner spacers 226a-226e and the middle dielectric layer 226M is disposed between two vertically adjacent channel layers 208. For example, the inner spacer 226b is disposed between the channel layer 208U2 and the channel layer 208U3, and the inner spacer 226c is disposed between the channel layer 208L1 and the channel layer 208L2. In some embodiments, the etch back process at block 110 may be a dry etch process that includes use of an oxygen-containing gas, hydrogen, nitrogen, a fluorine-containing gas (e.g., NF₃, CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof. In the illustrated embodiment, the inner spacers 226 and the middle dielectric layer 226M include the same dielectric material composition. Alternatively, the inner spacers 226 and the middle dielectric layer 226M may include different dielectric material compositions, such as by filling the gap 225M in a separate deposition process other than filling the inner spacer recesses 225.

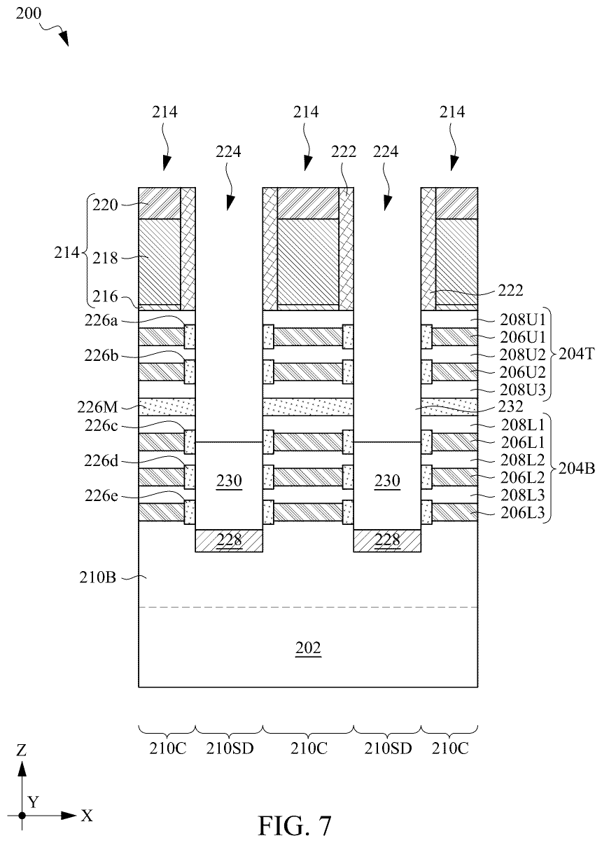

Referring to FIGS. 2 and 7, method 100 includes a block 112 where a leakage blocking layer 228 are formed in the source/drain trenches 224 and bottom source/drain features 230 are formed over the leakage blocking layer 228 in the source/drain trenches 224. The leakage blocking layer 228 functions to reduce leakage into the substrate 202. The leakage blocking layer 228 may include undoped semiconductor material or a dielectric material. In some embodiments, the leakage blocking layer 228 includes an undoped semiconductor material, such as undoped silicon (Si), undoped silicon germanium (SiGe), or undoped germanium (Ge). Alternatively, the leakage blocking layer 228 may be a dielectric layer, such as an oxide layer or a nitride layer. In these embodiments, the leakage blocking layer 228 may be deposited using vapor-phase epitaxy (VPE), ultra-high vacuum chemical vapor deposition (UHV-CVD), molecular beam epitaxy (MBE), and/or other suitable epitaxy deposition processes.

Still referring to FIG. 7, after the formation of the leakage blocking layer 228, the bottom source/drain features 230 may be formed using an epitaxial process, such as VPE, UHV-CVD, MBE, and/or other suitable processes. The epitaxial growth process may use gaseous and/or liquid precursors, which interact with the exposed sidewalls of the bottom channel layers 208L2 and 208L3. The leakage blocking layer 228 blocks the epitaxial growth of the bottom source/drain features 230 from the top surface of the substrate 202. In some alternative embodiments, if the formation of the leakage blocking layer 228 is optionally skipped, the epitaxial growth of bottom source/drain features 230 may take place from both the top surface of the substrate 202 and the exposed sidewalls of the channel layers 208. As illustrated in FIG. 7, the bottom source/drain features 230 are in physical contact with (or adjoining) the channel layers 208L2 and 208L3. Depending on the design, the bottom source/drain features 230 may be n-type or p-type. In the depicted embodiments, the bottom source/drain features 230 are p-type source/drain features and may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process.

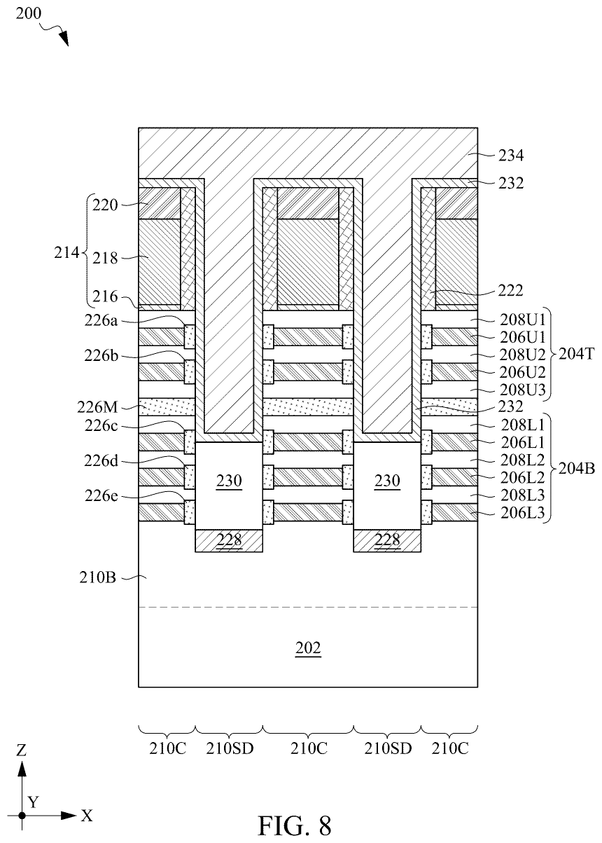

Referring to FIGS. 2 and 8, method 100 includes a block 114 where a bottom contact etch stop layer (CESL) 232 and a bottom interlayer dielectric (ILD) layer 234 are deposited over the bottom source/drain features 230. The bottom CESL 232 may include silicon nitride, silicon oxynitride, and/or other materials and may be formed by CVD, ALD, plasma-enhanced chemical vapor deposition (PECVD) process and/or other suitable deposition or oxidation processes. In an embodiment, the bottom CESL 232 includes silicon nitride, and a ratio of nitrogen concentration to silicon concentration (i.e., N/Si) of the bottom CESL 232 is in a range between about 1.1 and about 1.3. In some embodiments, the bottom CESL 232 is first conformally deposited on the workpiece 200 and the bottom ILD layer 234 is deposited over the bottom CESL 232 by spin-on coating, flowable CVD (FCVD), CVD, or other suitable deposition technique. The bottom ILD layer 234 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A dielectric constant of the bottom CESL 232 is greater than a dielectric constant of the bottom ILD layer 234.

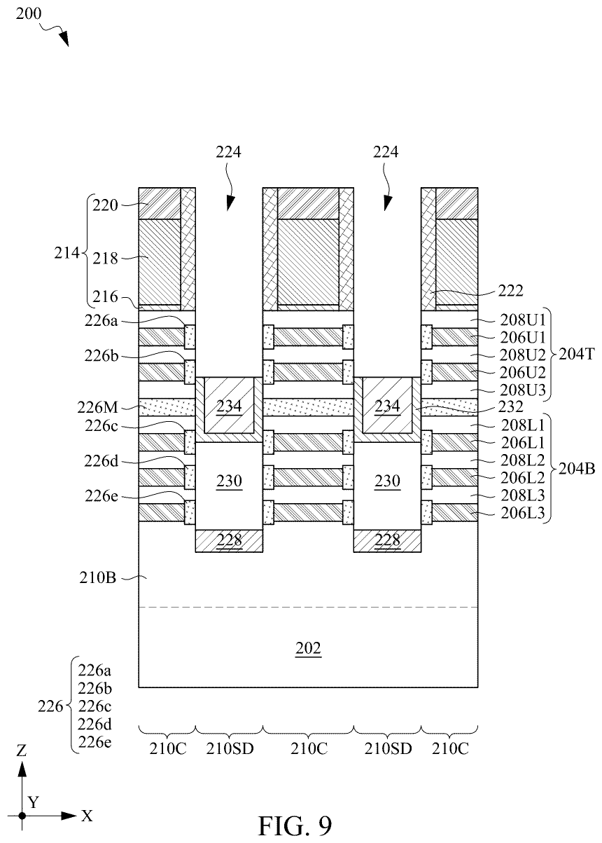

Referring to FIGS. 2 and 9, method 100 includes a block 116 where the bottom CESL 232 and the bottom ILD layer 234 are etched back. In the illustrated embodiment, the bottom CESL 232 and the bottom ILD layer 234 are etched back to exposed sidewalls of the channel layers 208U1 and 208U2. After being etched back, the bottom CESL 232 is in direct contact with the inner spacers 226b-226c, the channel layers 208U3, 208L1, and the middle dielectric layer 226M.

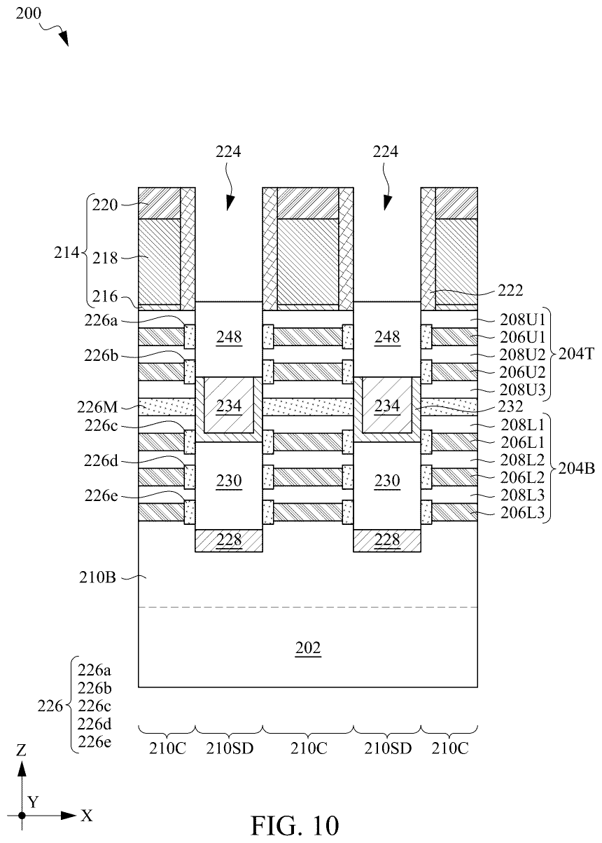

Referring to FIGS. 2 and 10, method 100 includes a block 118 where top source/drain features 248 are formed over the bottom CESL 232 and the bottom ILD layer 234. The top source/drain features 248 may be formed using an epitaxial process, such as VPE, UHV-CVD, MBE, and/or other suitable processes. The epitaxial growth process may use gaseous and/or liquid precursors, which interact with composition of the channel layers (e.g., channel layers 208U1 and 208U2) of the top portion 204T of the superlattice structure 204. The epitaxial growth of top source/drain features 248 may take place from the exposed sidewalls of the top channel layers 208U1 and 208U2. The deposited top source/drain features 248 are in physical contact with (or adjoining) the channel layers of the top portion 204T of the superlattice structure 204. Depending on the design, the top source/drain features 248 may be n-type or p-type. In the depicted embodiments, the top source/drain features 248 are n-type source/drain features and may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process.

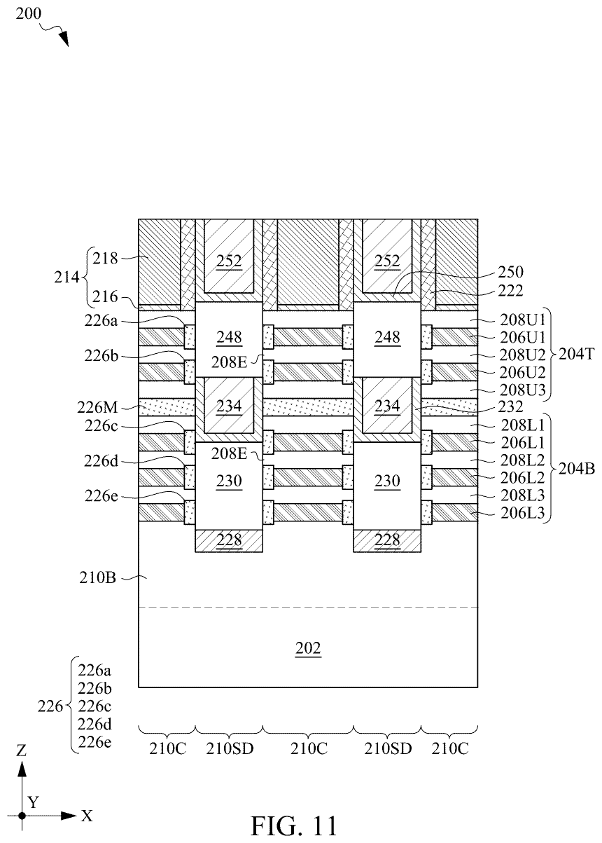

Referring to FIGS. 2 and 11, method 100 includes a block 120 where a top CESL 250 and a top ILD layer 252 are deposited over the top source/drain features 248. The top CESL 250 may include silicon nitride, silicon oxynitride, and/or other materials known in the art and may be formed by CVD, ALD, plasma-enhanced chemical vapor deposition (PECVD) process and/or other suitable deposition or oxidation processes. In some embodiments, the top CESL 250 is first conformally deposited on the workpiece 200 and the top ILD layer 252 is then deposited over the top CESL 250 by spin-on coating, FCVD, CVD, or other suitable deposition technique. The top ILD layer 252 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A dielectric constant of the bottom CESL 250 is greater than a dielectric constant of the bottom ILD layer 252. After formation of the top ILD layer 252, the workpiece 200 may be planarized by a planarization process to remove excess materials to expose the dummy gate stacks 214. For example, the planarization process may include a chemical mechanical planarization (CMP) process. In the illustrated embodiment, the gate-top hard mask layer 220 is also removed by the CMP process.

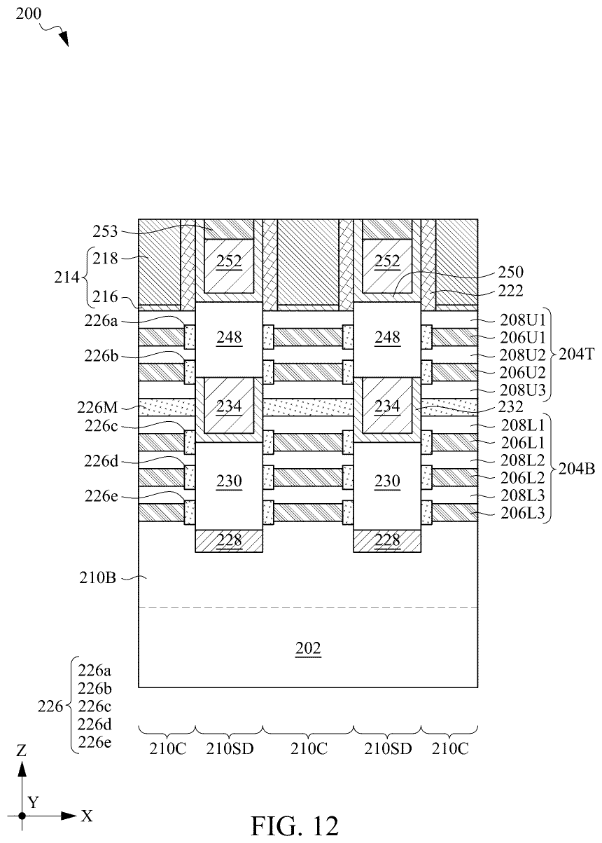

Referring to FIGS. 2 and 12, method 100 includes a block 122 where a capping layer 253 is formed on the top ILD layer 252. The capping layer 253 is formed from a different dielectric material than the top ILD layer 252 and serves as a protective layer to prevent damage to the top ILD layer 252 during subsequent etching processes. In some embodiments, the top ILD layer 252 is selectively recessed to form a top recess, over which the capping layer 253 is deposited. The capping layer 253 may include silicon nitride, silicon carbonitride, silicon carbide, or silicon oxycarbonitride. In one embodiment, the capping layer 253 consists of silicon nitride. A planarization process is then performed to remove excess dielectric material from the capping layer 253 and expose the dummy gate stacks 214. For example, the planarization process may include another CMP process. After planarization, the top surfaces of the capping layer 253, top CESL 250, gate spacers 222, and dummy gate stacks 214 are coplanar.

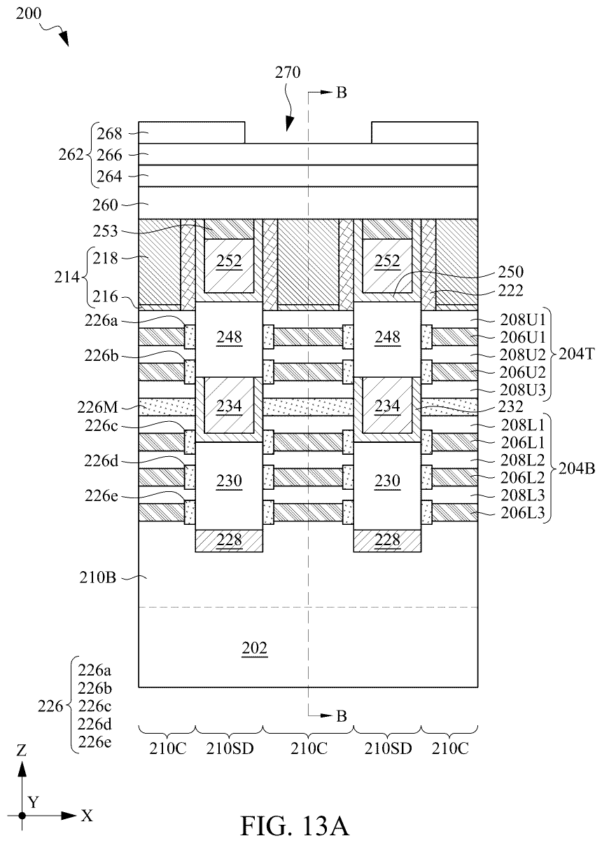

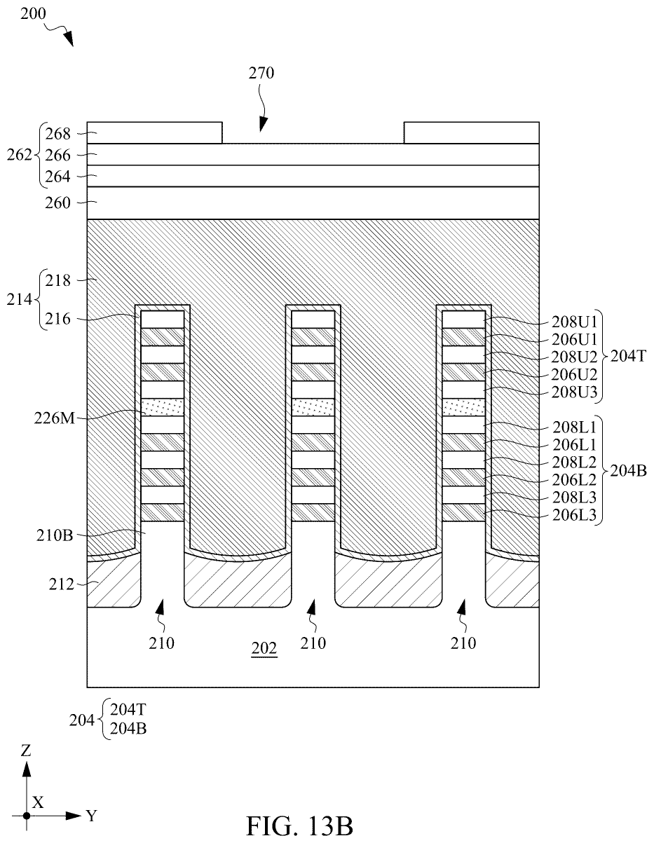

Referring to FIGS. 2 and 13A-13B, method 100 includes a block 124 where a hard mask layer 260 is formed over the workpiece 200 and an etching mask 262 is formed over the hard mask layer 260. FIG. 13A depicts a cross-sectional view of the workpiece 200 in the X-Z plane, and FIG. 13B depicts a cross-sectional view of the workpiece 200 in the Y-Z plane, which is taken along cutline B-B shown in FIG. 13A. The hard mask layer 260 may be a single-layer hard mask formed of, such as silicon nitride, silicon oxynitride, or the like, using a suitable formation method such as CVD. In some embodiments, the hard mask layer 260 is a multi-layered structure. For example, the hard mask layers 260 may include a silicon layer sandwiched between two silicon nitride layers. The etching mask 262 may have a single-layered structure (which may include a photoresist layer), or a dual-layered structure including a Bottom Anti-reflective Coating (BARC) layer and a photoresist layer. In the depicted embodiment, the etching mask 262 has a tri-layered structure, which includes a bottom layer 264 (e.g., a BARC layer), a middle layer 266 (e.g., a silicon nitride layer, or a silicon oxynitride layer), and a top layer 268 (e.g., a photoresist layer). In the illustrated embodiment, the top layer 268 includes an opening 270 above one of the fin-shaped structures 210. The opening 270 may be formed by a lithography process.

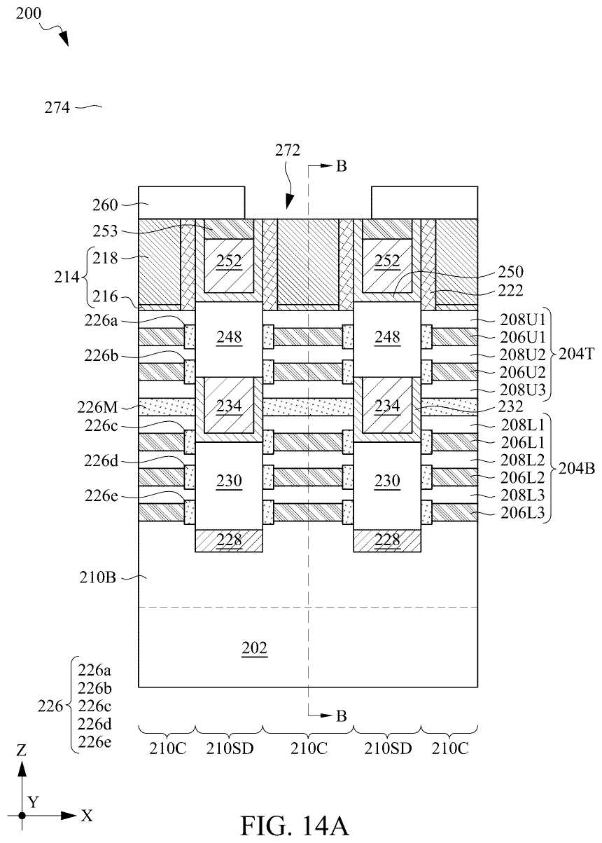

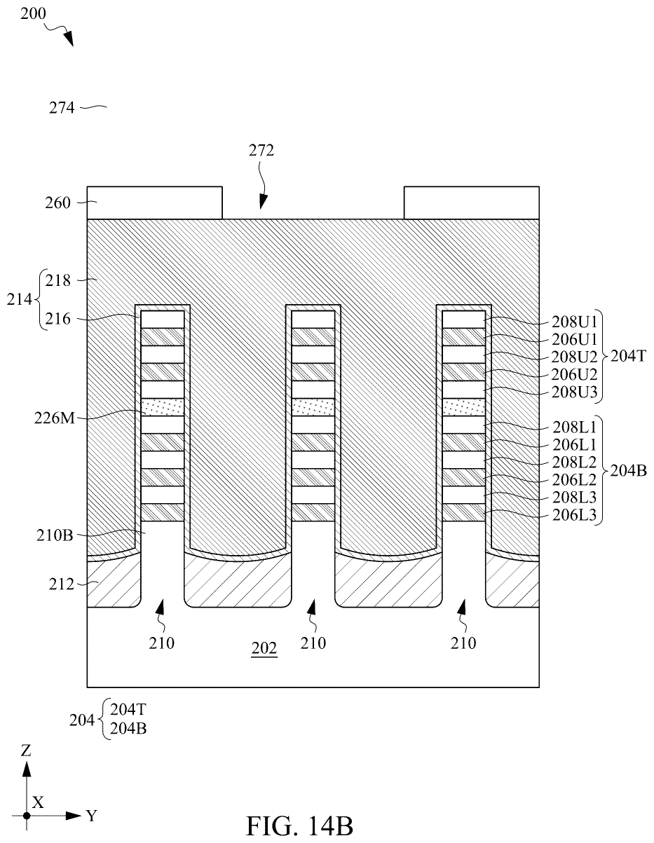

Referring to FIGS. 2 and 14A-14B, method 100 includes a block 126 where the opening 270 is transferred to the hard mask layer 260 as an opening 272 in the hard mask layer 260. FIG. 14A depicts a cross-sectional view of the workpiece 200 in the X-Z plane, and FIG. 14B depicts a cross-sectional view of the workpiece 200 in the Y-Z plane, which is taken along cutline B-B shown in FIG. 14A. Operations at block 126 may include extending the opening 270 in the top layer 268 through the middle layer 266 and bottom layer 264, then transferring the opening 270 to the hard mask layer 260 as opening 272 using a suitable method, such as one or more anisotropic etching processes. Next, the etching mask 262 is removed by a suitable process, such as etching, ashing, or a combination thereof.

The opening 272 exposes a segment of the dummy gate stack 214, allowing its removal and replacement with an isolation structure in subsequent processing. The removal of the exposed dummy gate stack 214 is also referred to as a CPODE process, the resulting trench as a CPODE trench, and the isolation structure filling the trench as a CPODE feature, details of which are discussed hereinafter. Notably, as shown in FIG. 14A, the selected dielectric material compositions for the gate spacers 222, top CESL 250, and capping layer 253 enlarge the processing window, such that exact location of the edges of the opening 272 become insensitive. Subsequent selective etching processes are thereby confined to the exposed segment of the dummy gate stack 214 without substantially etching adjacent dielectric features, even if one or more top surfaces of the gate spacers 222, top CESL 250, and capping layer 253 are exposed by the opening 272.

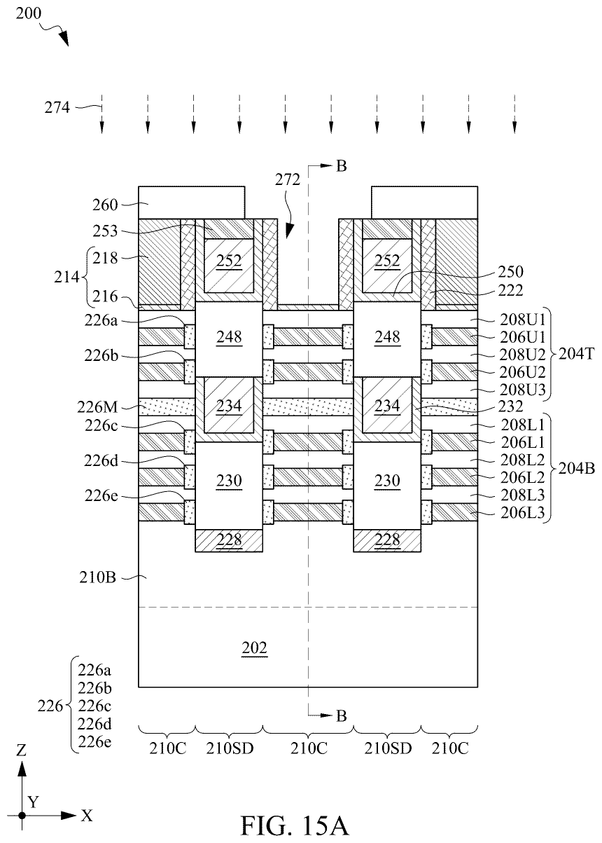

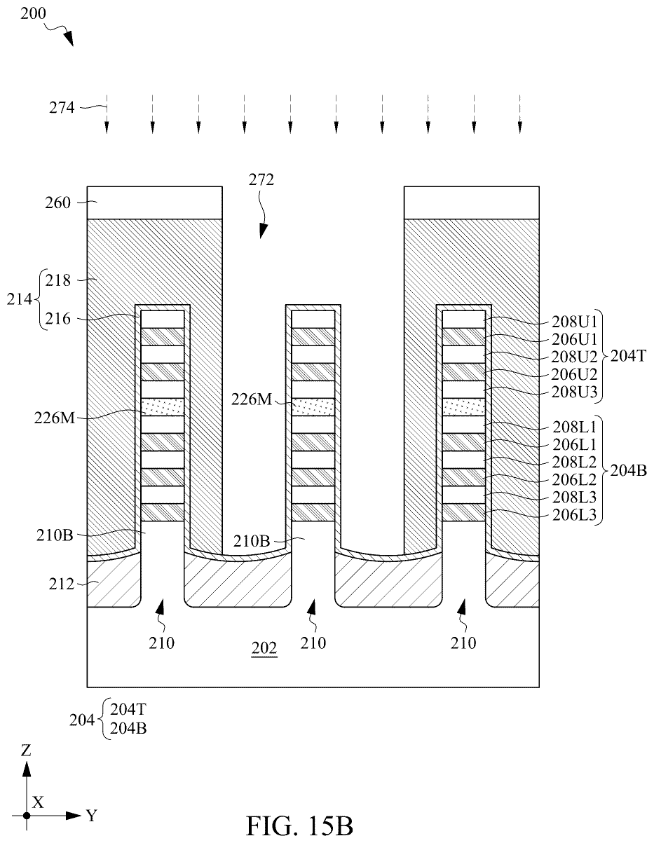

Referring to FIGS. 2 and 15A-15B, method 100 includes a block 128 where an etching process 274 is performed to extend the opening 272 through the exposed segment of the dummy gate stack 214. FIG. 15A depicts a cross-sectional view of the workpiece 200 in the X-Z plane, and FIG. 15B depicts a cross-sectional view of the workpiece 200 in the Y-Z plane, which is taken along cutline B-B shown in FIG. 15A. The extended opening 272 is also referred to as the CPODE trench 272. The CPODE trench 272 exposes the dummy dielectric layer 216. The dummy dielectric layer 216 may serve as an etch stop layer during the etching process 274. In the illustrated embodiment, the etching process 274 is an anisotropic etching process, which may include a dry etching process or a suitable etch process. For example, the dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As shown in FIG. 15A, the gate spacers 222 substantially remain intact during the etching process 274 and limit the etching process 274 between the opposing sidewalls of the gate spacers 222 in the X-Z plane.

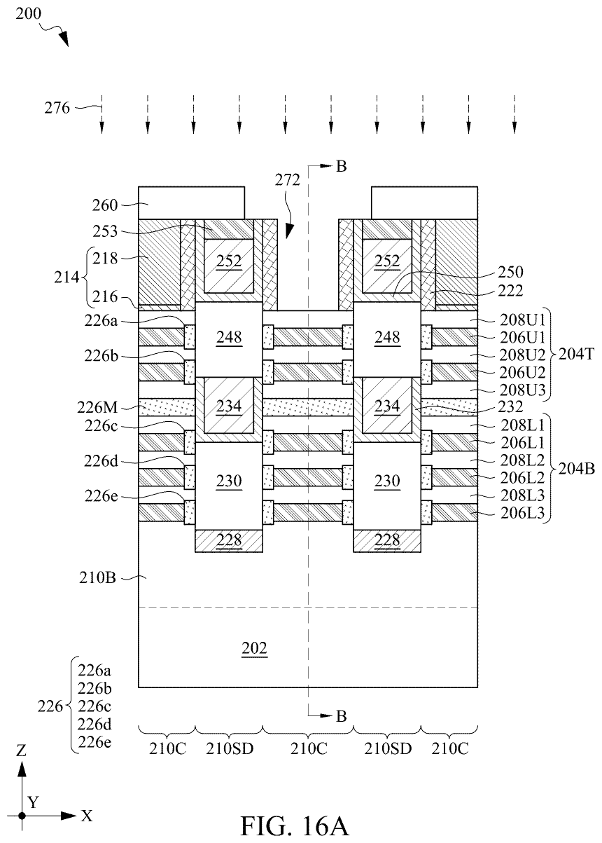

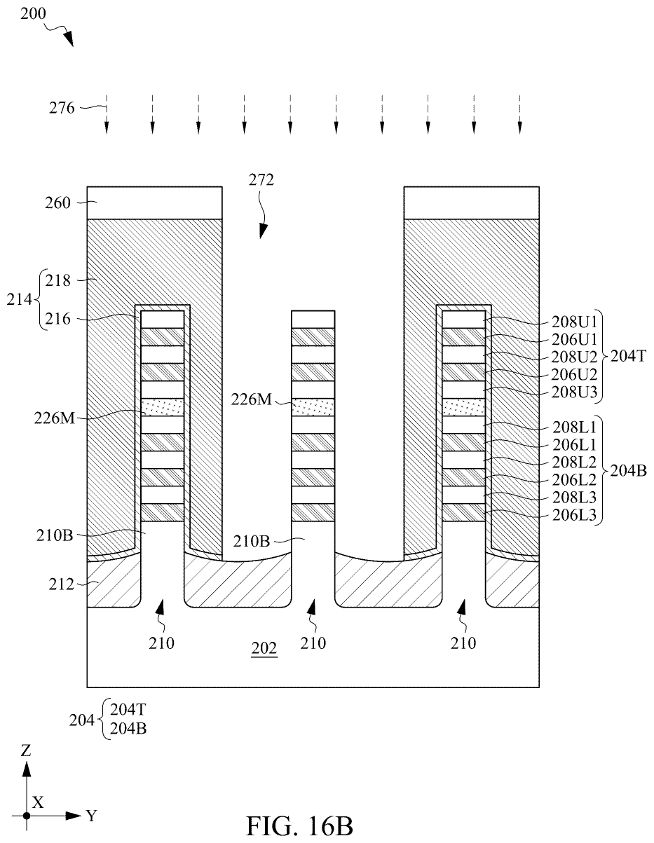

Referring to FIGS. 2 and 16A-16B, method 100 includes a block 130 where an etching process 276 is performed to remove the dummy dielectric layer 216 from the CPODE trench 272. FIG. 16A depicts a cross-sectional view of the workpiece 200 in the X-Z plane, and FIG. 16B depicts a cross-sectional view of the workpiece 200 in the Y-Z plane, which is taken along cutline B-B shown in FIG. 16A. In the illustrated embodiment, the etching process 276 is an isotropic etching process (e.g., dry chemical etching or wet etching). Alternatively, the etching process 276 may be an anisotropic etching process (e.g., dry plasma etching). Upon removal of the dummy dielectric layer 216, the fin-shaped structure 210 becomes exposed within the CPODE trench 272. Specifically, the sidewalls of the channel layers 208, sacrificial layers 206, and middle dielectric layer 206M, and the top surfaces of the isolation feature 212 and the topmost channel layer 208U1 are exposed in the CPODE trench 272.

The exposure of the fin-shaped structure 210 in the CPODE trench 272 enables the removal of the fin-shaped structure 210. Notably, the presence of the middle dielectric layer 226M poses challenges for the etching process. Specifically, a single etch step to remove the channel layers 208, sacrificial layers 206, and middle dielectric layer 226M collectively would compromise the integrity of adjacent dielectric features, such as the gate spacers 222 and inner spacers 226, due to low etching selectivity. Conversely, an etching process that removes the channel layers 208 first, followed by the sacrificial layers 206, or both simultaneously, would require a duration sufficient to etch at least half the width (along the Y direction) of the channel layers 208 in the Y-Z plane. This prolonged etching may inadvertently etch through the relatively thin end portions (portions vertically stacked between the inner spacers 226) of the channel layers 208 in the X-Z plane, leading to undesired exposure of the source/drain features 230 and 248. As discussed in detail below, some embodiments of the present disclosure apply a selective etching process to remove the sacrificial layers 206 prior to the removal of the channel layers 208, while substantially preserving the middle dielectric layer 226M. This approach maintains the integrity of adjacent dielectric features and prevents the end portions of the channel layers 208 in the X-Z plane from being etched through.

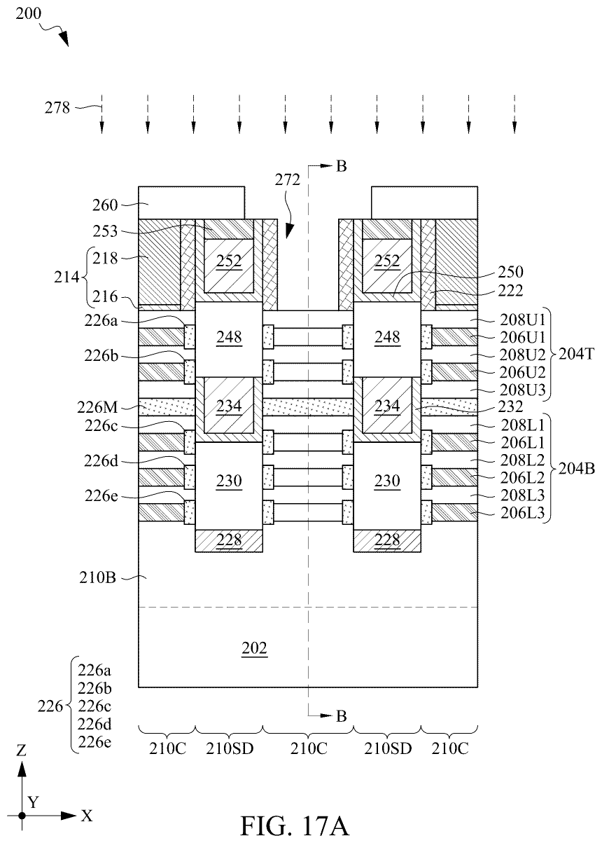

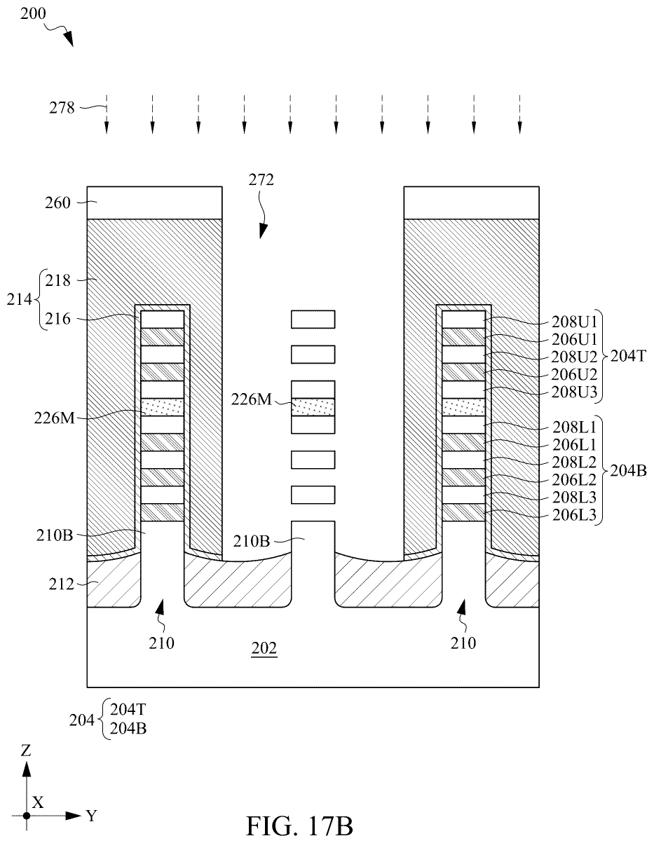

Referring to FIGS. 2 and 17A-17B, method 100 includes a block 132 where an etching process 278 is performed to remove the sacrificial layers 206 from the CPODE trench 272. FIG. 17A depicts a cross-sectional view of the workpiece 200 in the X-Z plane, and FIG. 17B depicts a cross-sectional view of the workpiece 200 in the Y-Z plane, which is taken along cutline B-B shown in FIG. 17A. In the illustrated embodiment, the etching process 278 is an isotropic etching process (e.g., dry chemical etching or wet etching), as the presence of the middle dielectric layer 226M would otherwise shield the underlying sacrificial layers 206 from removal if an anisotropic etching process were used. In some embodiments, the etching process 278 includes a dry chemical etching that employs vapor-phase etchants, such as xenon difluoride (XeF₂), to react with SiGe in the sacrificial layers 206 and form volatile byproducts. Dry chemical etching generally offers high selectivity toward SiGe, minimizing impact on adjacent silicon and dielectric materials. In some other embodiments, the etching process 278 includes remote plasma etching, which generates reactive radicals to facilitate the selective removal of SiGe while minimizing damage to surrounding materials. For example, nitrogen trifluoride (NF₃) and ammonia (NH₃) may be used in a remote plasma setup to produce reactive species that etch SiGe isotropically. Additionally, in some other embodiments, a wet etching process can be employed to selectively remove the sacrificial layers 206. For example, a wet etching solution containing a mixture of nitric acid (HNO₃), acetic acid (CH₃COOH), and hydrofluoric acid (HF) may be used to achieve high selectivity between SiGe and adjacent silicon and dielectric materials. Alternatively, a tetramethylammonium hydroxide (TMAH) or ammonium hydroxide (NH₄OH) solution with an oxidizing agent, such as hydrogen peroxide (H₂O₂), may be utilized to enhance etching selectivity.

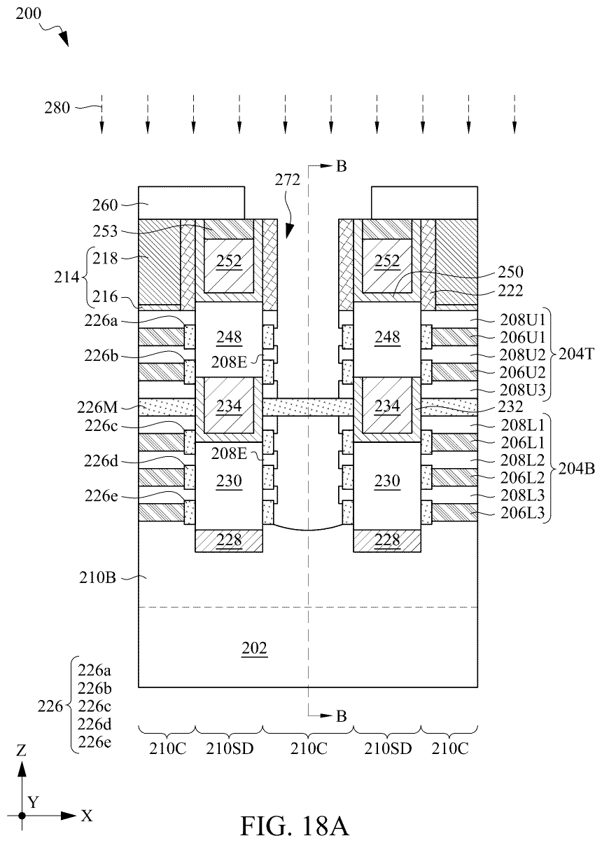

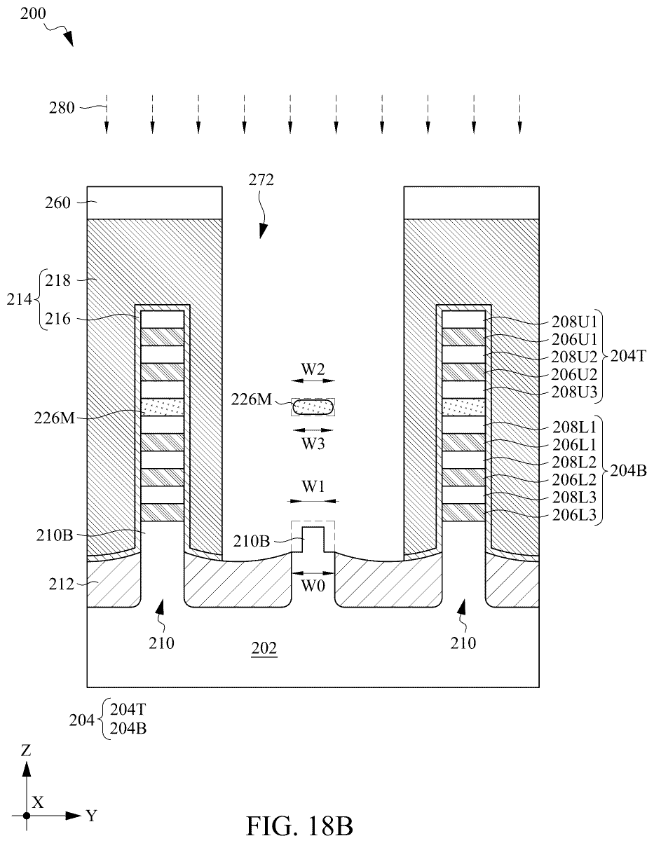

Referring to FIGS. 2 and 18A-18B, method 100 includes a block 134 where an etching process 280 is performed to remove the channel layers 208 from the CPODE trench 272. FIG. 18A depicts a cross-sectional view of the workpiece 200 in the X-Z plane, and FIG. 18B depicts a cross-sectional view of the workpiece 200 in the Y-Z plane, which is taken along cutline B-B shown in FIG. 18A. In the illustrated embodiment, the etching process 280 is an isotropic etching process (e.g., dry chemical etching or wet etching), as the presence of the middle dielectric layer 226M would otherwise shield the underlying channel layers 208 from removal if an anisotropic etching process were used. In some embodiments, the etching process 280 includes a dry chemical etching that employs vapor-phase etchants, such as HF vapor, to react with Si in the channel layers 208 and form volatile byproducts. In some other embodiments, the etching process 280 includes remote plasma etching, which generates reactive radicals to facilitate the selective removal of Si while minimizing damage to surrounding materials. For example, a mixture of CHF₃, CF₄, and Ar may be used in a remote plasma setup to produce reactive species that etch Si isotropically. Additionally, in some other embodiments, a wet etching process can be employed to selectively remove the channel layers 208 isotropically. For example, a wet etching solution containing potassium hydroxide (KOH) may be used to remove Si. Alternatively, a hydrofluoric, nitric, acetic acid (HNA) may be utilized to enhance etching selectivity.

The removal of the sacrificial layers 206 exposes the top and bottom surfaces of the channel layers 208U1, 208U2, 208L2, and 208L3, as well as the top surface of channel layer 208U3 and the bottom surface of channel layer 208L1. These exposed surfaces enable the etching process 280 to etch the channel layers 208 from the thickness direction, which takes significantly less time than etching from the width direction. Thus, in the X-Z plane (FIG. 18A), the end portions of the channel layers 208, denoted as 208E, remain well preserved, effectively plugging the gaps between adjacent inner spacers 226 and the gate spacers 222. These preserved end portions protect the source/drain features 230 and 248 from exposure. The length (along the X direction) of the remaining end portions 208E varies depending on the duration of the etching process 280. In the illustrated embodiment shown in FIG. 18A, the remaining end portions 208E protrude from the sidewalls of the inner spacers 226, extending closer towards the CPODE trench 272. Alternatively, the end portions 208E may have sidewalls that are flush with those of the inner spacers 226 or may be recessed relative to the inner spacers 226, extending closer toward the source/drain features 230 and 248.

As shown in FIG. 18B, the fin-shaped base 210B may also undergo width reduction (along the Y direction) and partial height recession due to the etching process 280. For comparison, the original contour of the fin-shaped base 210B before the etching process 280 is indicated by dashed lines in FIG. 18B. After etching, the top portion of the fin-shaped base 210B above the isolation feature 212 has a width (denoted as W1) smaller than the width (denoted as W0) of the bottom portion below the isolation feature 212 (i.e., W1<W0). Additionally, the height of the top portion exposed within the CPODE trench 272 is reduced compared to other fin-shaped bases 210B. Similarly, as illustrated in FIG. 18A, the top surface of the fin-shaped base 210B exposed in the CPODE trench 272 may exhibit a dishing profile, making it lower than the covered portions of the fin-shaped base 210B.

Also, as shown in FIG. 18B, the middle dielectric layer 226M may experience some etching loss due to non-ideal etching selectivity. Compared to unexposed middle dielectric layers 226M, the exposed one may exhibit rounded corners rather than right-angle corners. Both the width and thickness of the exposed middle dielectric layer 226M may be reduced. For comparison, the original contour of the middle dielectric layer 226M before the etching process 280 is indicated by dashed lines in FIG. 18B. After etching, the reduced width (denoted as W3) of the middle dielectric layer 226M is smaller than its original width (denoted as W2) (i.e., W3<W2). Additionally, the original width W2 may be approximately equal to the width W0 of the bottom portion of the fin-shaped base 210B. The reduced width W3 becomes narrower than W0 but remains wider than the reduced width W1 of the top portion of the fin-shaped base 210B (i.e., W1<W3<W2≈W0).

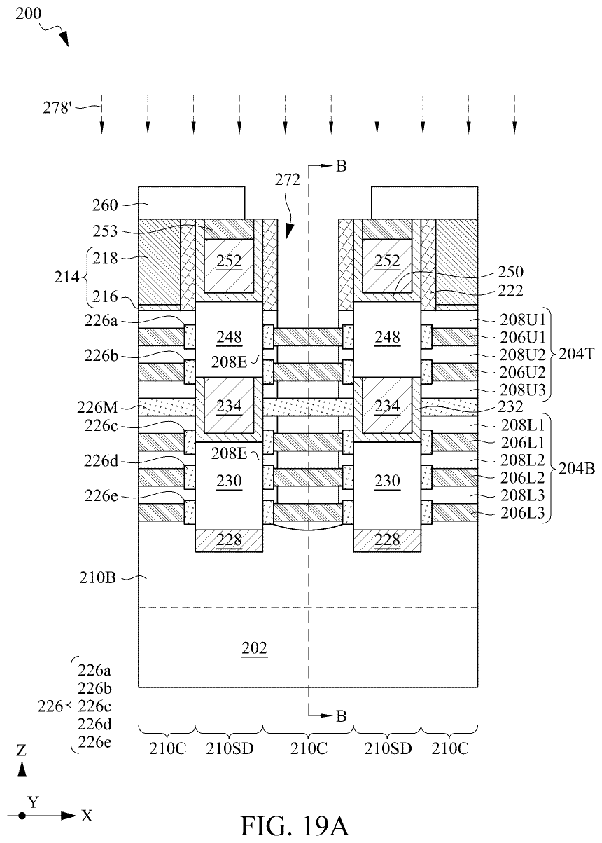

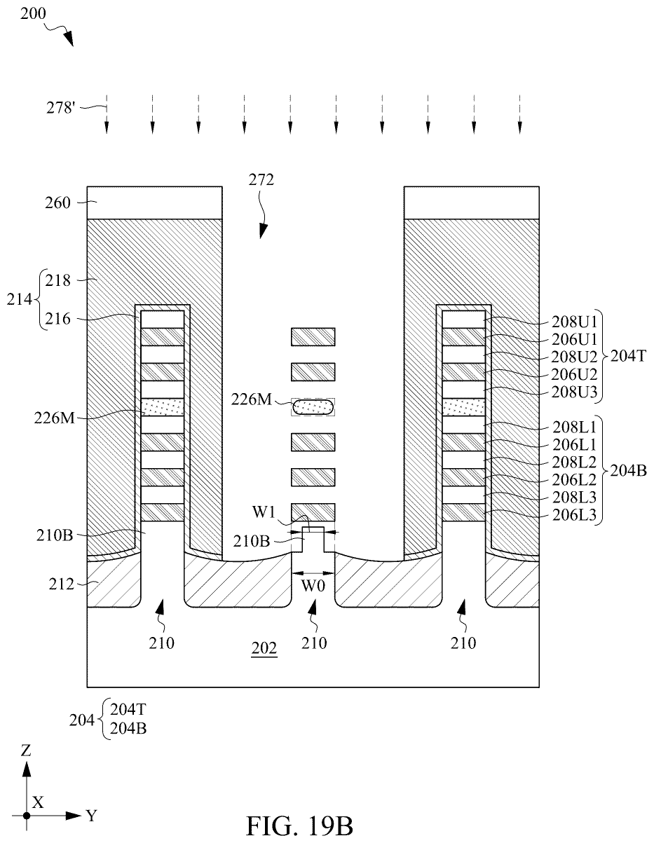

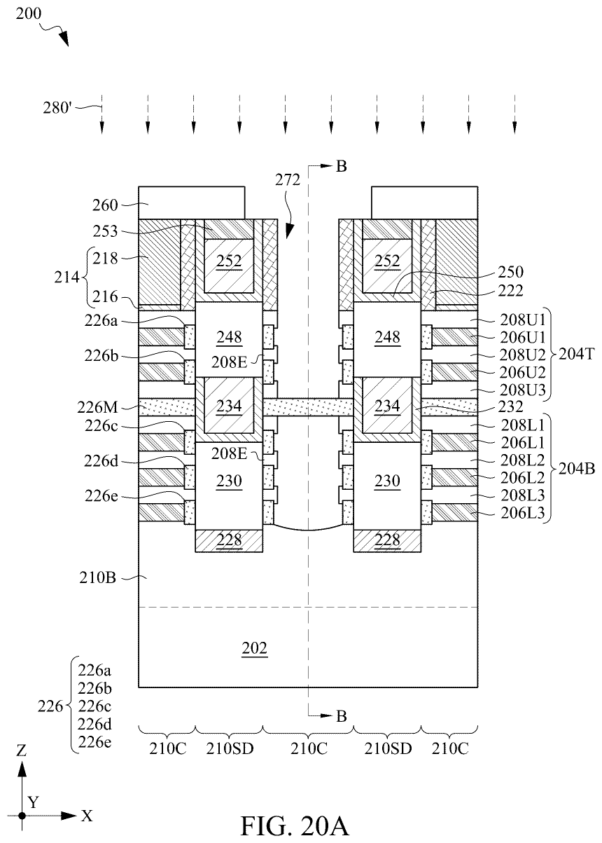

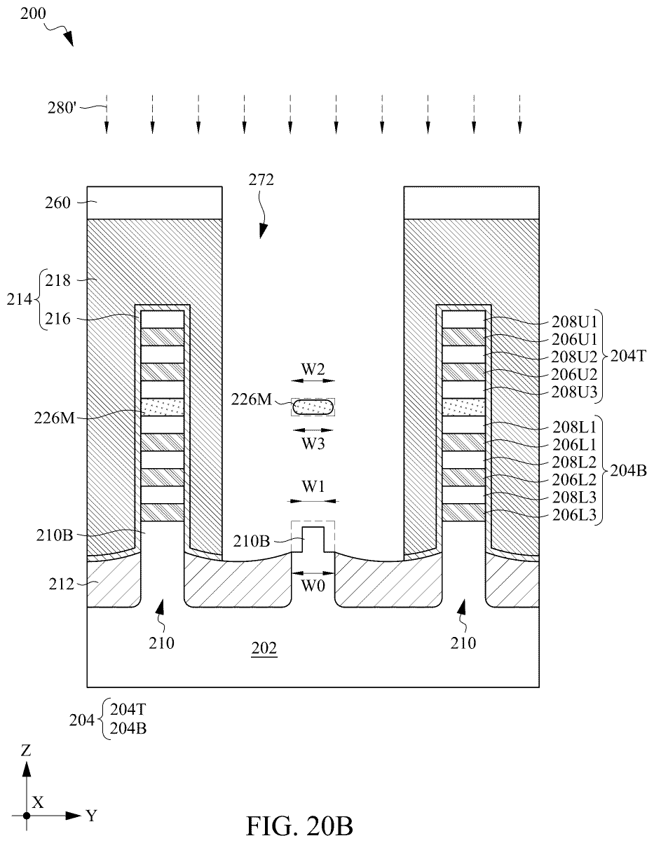

FIGS. 19A, 19B, 20A, and 20B illustrate an alternative embodiment in releasing the middle dielectric layer 226M in the CPODE trench 272, in which a first etching process 278′ removes the channel layers 208 prior to the removal of the sacrificial layers 206 in a second etching process 280′. FIG. 19A depicts a cross-sectional view of the workpiece 200 in the X-Z plane, and FIG. 19B depicts a cross-sectional view of the workpiece 200 in the Y-Z plane, which is taken along cutline B-B shown in FIG. 19A. In the illustrated embodiment, the etching process 278′ is an isotropic etching process (e.g., dry chemical etching or wet etching), as the presence of the middle dielectric layer 226M would otherwise shield the underlying channel layers 208 from removal if an anisotropic etching process were used. The fin-shaped base 210B may also undergo width reduction (along the Y direction) and partial height recession due to the etching process 278′. The middle dielectric layer 226M may experience some etching loss due to non-ideal etching selectivity. Compared to unexposed middle dielectric layers 226M, the exposed one may exhibit rounded corners rather than right-angle corners. Both the width and thickness of the exposed middle dielectric layer 226M may be reduced, as shown in FIG. 19B. FIG. 20A depicts a cross-sectional view of the workpiece 200 in the X-Z plane, and FIG. 20B depicts a cross-sectional view of the workpiece 200 in the Y-Z plane, which is taken along cutline B-B shown in FIG. 20A. In the illustrated embodiment, the etching process 280′ is an isotropic etching process (e.g., dry chemical etching or wet etching), as the presence of the middle dielectric layer 226M would otherwise shield the underlying sacrificial layers 206 from removal if an anisotropic etching process were used. The middle dielectric layer 226M may experience further etching loss due to non-ideal etching selectivity. Both the width and thickness of the exposed middle dielectric layer 226M may be further reduced, as shown in FIG. 20B.

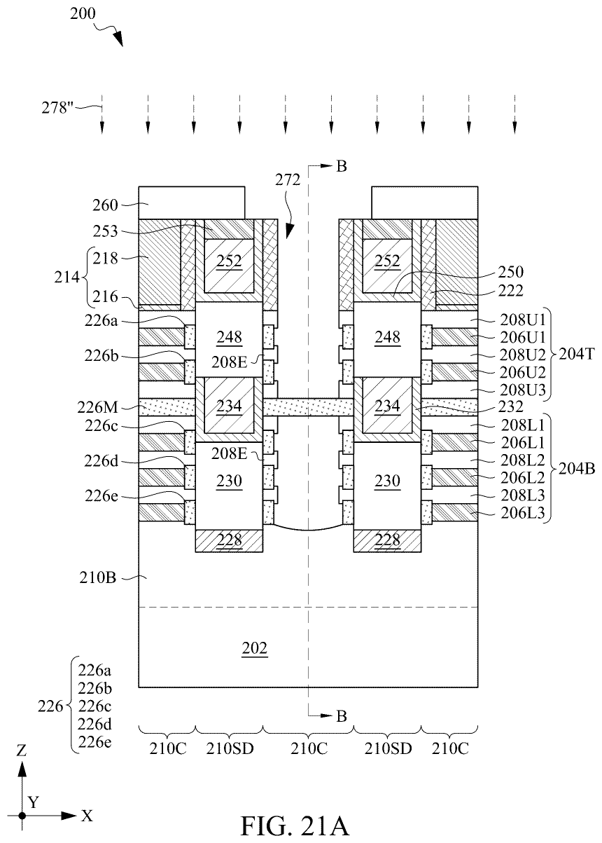

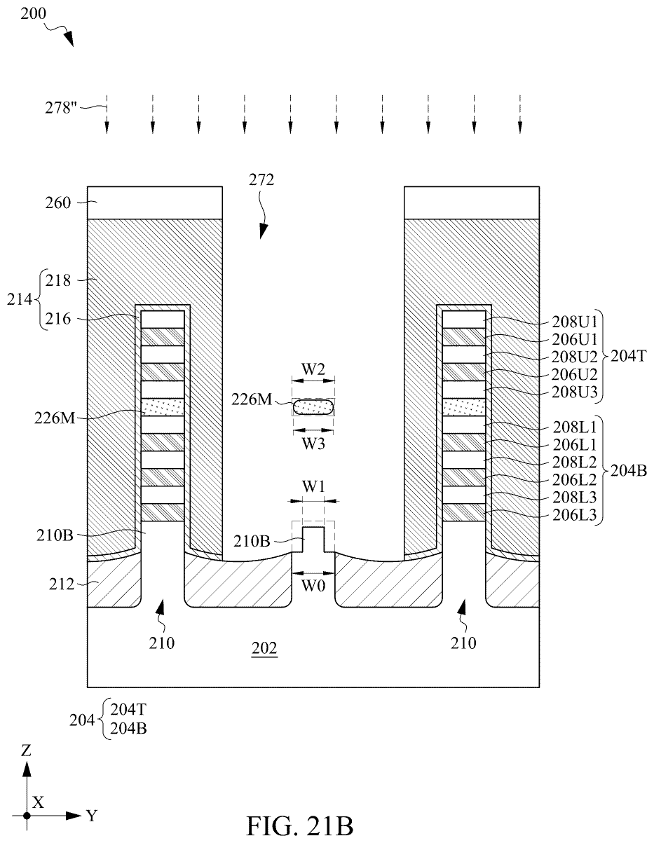

FIGS. 21A and 21B illustrate another alternative embodiment in releasing the middle dielectric layer 226M in the CPODE trench 272, in which an etching process 278″ removes the channel layers 208 and the sacrificial layers 206 collectively. In the illustrated embodiment, the etching process 278″ is an isotropic etching process (e.g., dry chemical etching or wet etching), as the presence of the middle dielectric layer 226M would otherwise shield the underlying channel layers 208 and sacrificial layers 206 from removal if an anisotropic etching process were used. The etchant of the etching process 278″ is selected such that the etchant etches the channel layers 208 and the sacrificial layers 206 simultaneously under less contrast etching rates.

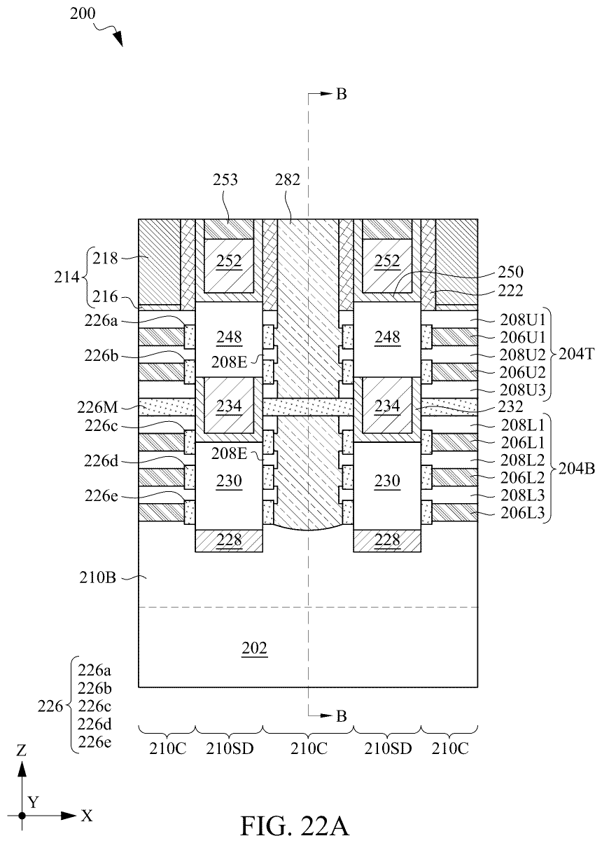

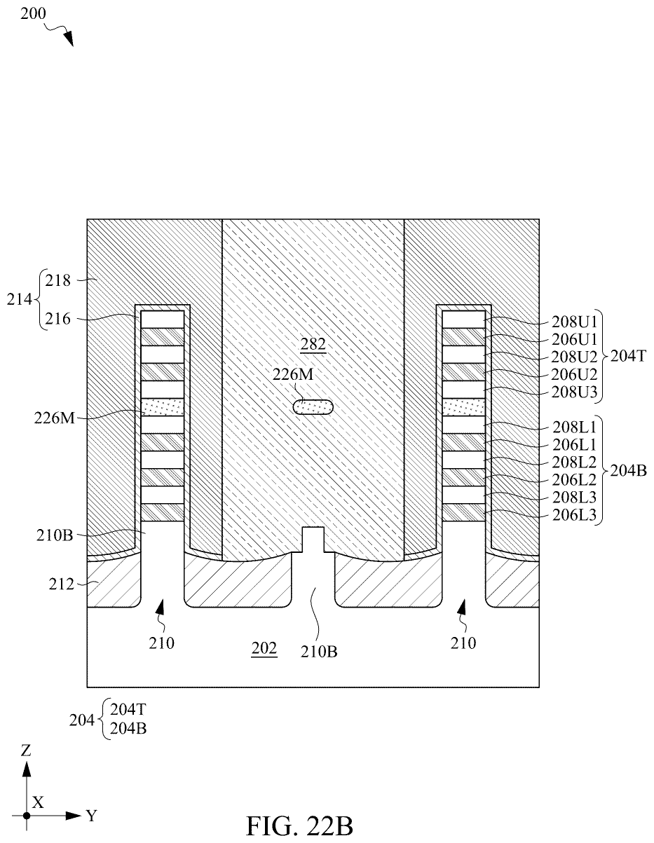

Referring to FIGS. 2 and 22A-22B, method 100 includes a block 136 where an isolation structure 282 is formed in the CPODE trench 272. FIG. 22A depicts a cross-sectional view of the workpiece 200 in the X-Z plane, and FIG. 22B depicts a cross-sectional view of the workpiece 200 in the Y-Z plane, which is taken along cutline B-B shown in FIG. 22A. The isolation structure 282, also referred to as the CPODE feature 282, can be configured as either a single-layer or a multi-layer structure. In the case of a single-layer structure, the CPODE feature 282 may consist of an oxygen-free dielectric layer. In some embodiments, this oxygen-free dielectric layer may include a nitride material (e.g., silicon nitride or silicon carbonitride) and can be deposited using ALD, CVD, PVD, or other suitable processes. For a multi-layer structure, a dielectric liner (not shown) may first be conformally deposited on the sidewalls and bottom surface of the CPODE trench 272, as well as wrapping around the middle dielectric layer 226M, such as by an ALD process. In some embodiments, the dielectric liner comprises a nitride material (e.g., silicon nitride or silicon carbonitride) and can be deposited using ALD, CVD, PVD, or other suitable processes. Subsequently, a dielectric layer is deposited into the CPODE trench 272 to fill the trench using ALD, CVD, PVD, or other suitable processes. In some embodiments, this dielectric layer may be an oxide (e.g., silicon oxide) or a nitride (e.g., silicon nitride or silicon carbonitride) that is compositionally different from the dielectric liner. The dielectric liner and the dielectric layer collectively define the CPODE feature 282. Upon completion of block 136, a planarization process, such as CMP, may be performed to remove excess dielectric materials and the hard mask layer 260, thereby exposing other dummy gate stacks 214.

In the illustrated embodiment shown in FIG. 22A, the CPODE feature 282 is in direct contact with the sidewalls of the gate spacers 222, inner spacers 226, and end portions 208E of the removed channel layers 208. Due to the protrusion of the end portions 208E, sidewalls of the CPODE feature 282 have protruding portions that are vertically stacked between respective adjacent end portions 208E. As previously discussed, in some embodiments, the end portions 208E may be recessed relative to the inner spacers 226. In such cases, instead, sidewalls of the CPODE feature 282 have protruding portions vertically stacked between respective adjacent inner spacers 226. Also referring to FIG. 22B, the CPODE feature 282 wraps around the middle dielectric layer 226M. In some embodiments, the middle dielectric layer 226M and the CPODE feature 282 are composed of different dielectric materials. In alternative embodiments, the middle dielectric layer 226M and the CPODE feature 282 may share the same dielectric material composition, though the interface between the middle dielectric layer 226M and the CPODE feature 282 remains discernible.

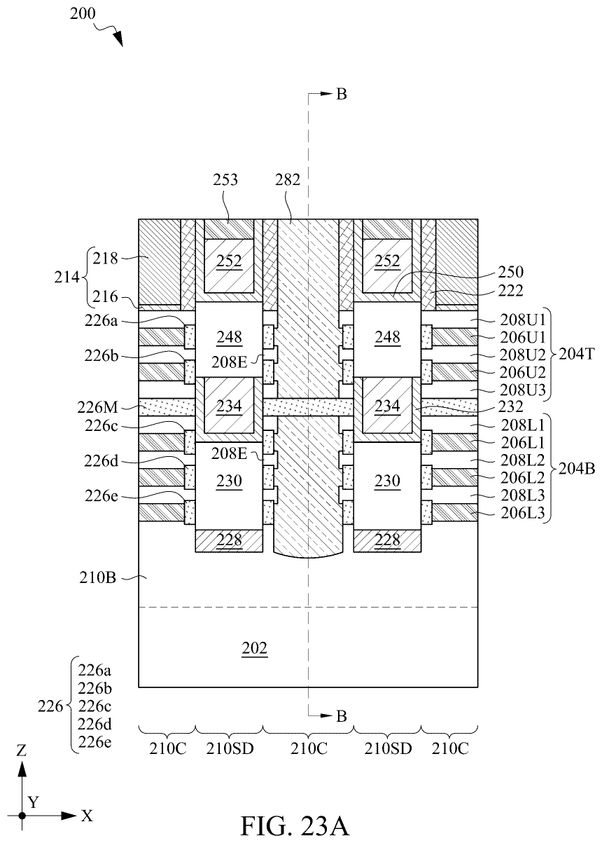

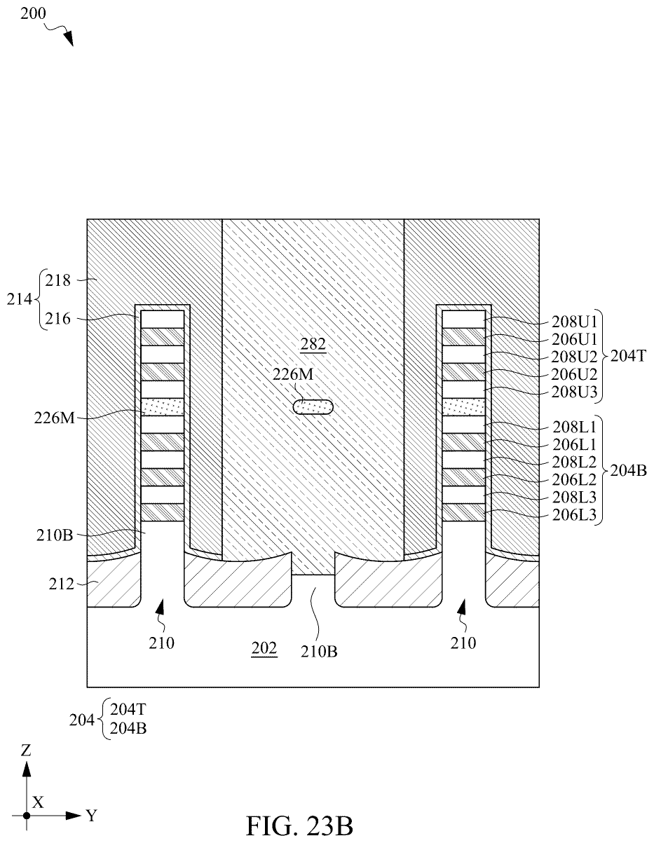

In FIG. 22B, the top portion of the fin-shaped base 210B rises above the top surface of the isolation feature 212 and protrudes into the bottom portion of the CPODE feature 282. FIGS. 23A and 23B illustrate an alternative embodiment, in which the bottom portion of the CPODE feature 282 extends below the top surface of the isolation feature 212 instead. FIG. 23A depicts a cross-sectional view of the workpiece 200 in the X-Z plane, and FIG. 23B depicts a cross-sectional view of the workpiece 200 in the Y-Z plane, which is taken along cutline B-B shown in FIG. 23A. Previous etching process(es) in the releasing of the middle dielectric layer 226M from the CPODE trench 272 may have recessed the fin-shaped base 210B below the top surface of the isolation feature 212, such that the bottom portion of the CPODE feature 282 extends further downward and under the top surface of the isolation feature 212. The extended bottom surface of the CPODE feature 282 may be even lower than the leakage blocking layer 228, as shown in FIG. 23A.

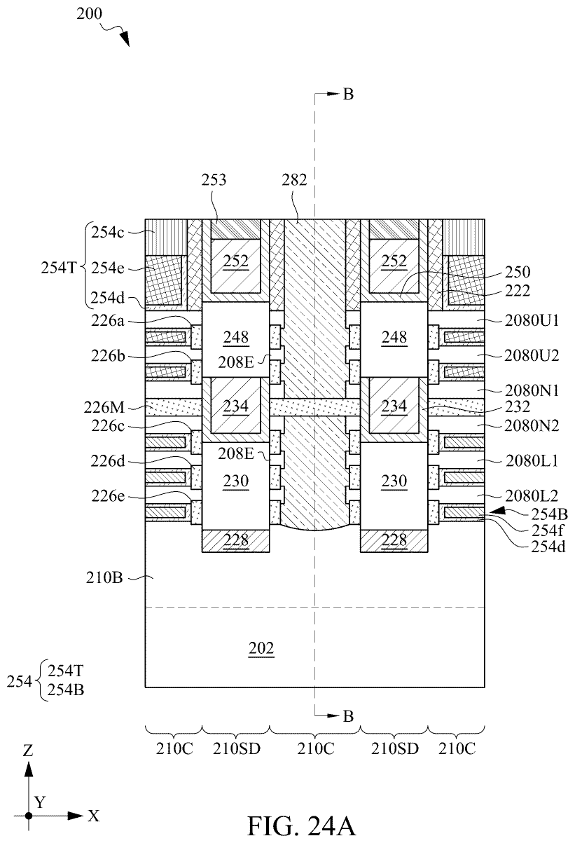

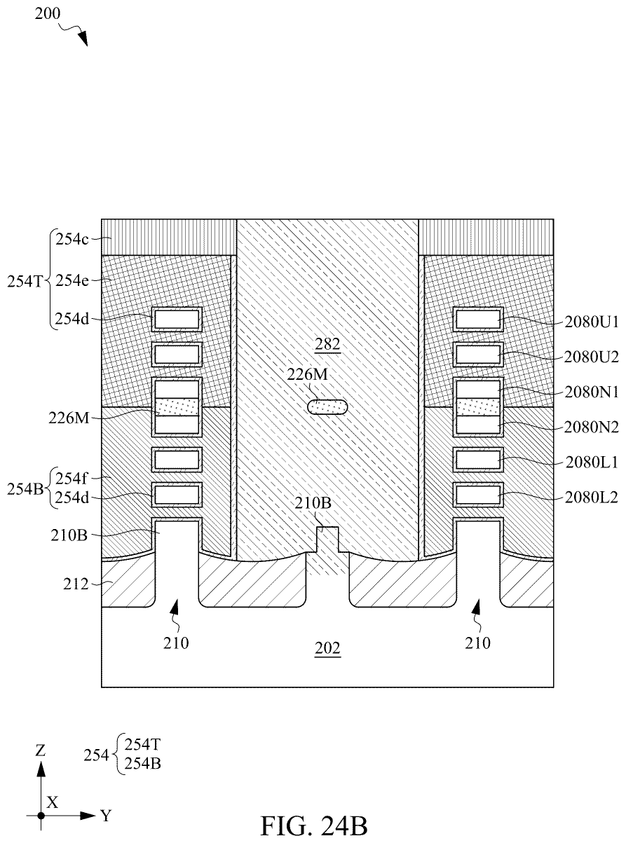

Referring to FIGS. 2 and 24A-24B, method 100 includes a block 138 where the dummy gate stacks 214 are replaced with gate structures 254. FIG. 24A depicts a cross-sectional view of the workpiece 200 in the X-Z plane, and FIG. 24B depicts a cross-sectional view of the workpiece 200 in the Y-Z plane, which is taken along cutline B-B shown in FIG. 24A. Operations at block 138 may include removal of the dummy gate stacks 214, release of the channel layers 208 as channel members (including top channel members 2080U1, 2080U2, and bottom channel members 2080L1, and 2080L2) and nanostructures (including the nanostructures 2080N1 and 2080N2) and formation of gate structures 254 to wrap around the channel members 2080. The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. After the removal of the dummy gate stacks 214, sidewalls of the channel layers 208 and sacrificial layers 206 in the channel regions 210C are exposed. Thereafter, the sacrificial layers 206 in the channel regions 210C are selectively removed to release the channel layers 208 as the channel members (including the top channel members 2080U1, 2080U2, the bottom channel members 2080L1, and 2080L2) and nanostructures (including the nanostructures 2080N1 and 2080N2). The selective removal of the sacrificial layers 206 may be implemented by a selective dry etch, a selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH.

In the illustrated embodiment, the top channel members 2080U1 and 2080U2 are in direct contact with the top source/drain features 248; the bottom channel members 2080Ll and 2080L2 are in direct contact with the bottom source/drain features 230; and the nanostructures 2080N1, 2080N2 and the middle dielectric layer 226M are in direct contact with the bottom CESL 232.

After the selective removal of the sacrificial layers 206, the gate structure 254 is deposited to wrap around each of the top channel members 2080U1 and 2080U2 and bottom channel members 2080L1 and 2080L2, thereby forming a bottom multi-gate transistor (e.g., 10L in FIG. 1) and a top multi-gate transistor (e.g., 10U in FIG. 1) disposed over the bottom multi-gate transistor. In the depicted embodiments, both the bottom multi-gate transistor and the top multi-gate transistor are GAA transistors. In some embodiments, the gate structure 254 may be a common gate structure to engage the bottom channel members and the top channel members. In some other embodiments depicted in the drawings, the gate structure 254 includes a bottom gate portion 254B to engage bottom channel members 2080L1 and 2080L2 and a top gate portion 254T to engage the top channel members 2080U1 and 2080U2. The bottom gate portion 254B and the top gate portion 254T have different work function layers. For example, the bottom gate portion 254B may include n-type work function layers and the top gate portion 254T may include p-type work function layers. While not explicitly shown in the figures, the gate structure 254 includes an interfacial layer to interface the channel members. The gate structure 254 also includes a gate dielectric layer 254d over the interfacial layer, a work function layer 254e/254f (e.g., a p-type work function layer or an n-type work function layer). The gate dielectric layer 254d is deposited over the workpiece 200 using ALD, CVD, and/or other suitable methods. The gate dielectric layer 254d is formed of high-K dielectric materials. As used and described herein, high-k dielectric materials include dielectric materials having a high dielectric constant, for example, greater than that of thermal silicon oxide (˜3.9). A dielectric constant of the gate dielectric layer 254d is greater than a dielectric constant of the gate spacers 222. The gate dielectric layer 254d may include hafnium oxide. Alternatively, the gate dielectric layer 254d may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material.

After the deposition of the gate dielectric layer 254d, n-type work function layer 254e and the p-type work function layer 254f may be formed over the channel regions 210C. The p-type work function layer 254f and the n-type work function layer 254e may include a single layer or alternatively a multi-layer structure, such as various combinations of a metal layer with a selected work function to enhance the device performance (work function metal layer). By way of example, the p-type work function layer 254f may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The n-type work function layer 254e may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. The gate structure 254 may also include a metal fill to reduce contact resistance. In some instance, the metal fill includes tungsten (W). The gate structure 254 may also include a liner layer, a wetting layer, an adhesion layer, a metal alloy or a metal silicide. In the depicted embodiment, the top gate portion 254T also includes a dielectric capping layer 254c formed over the n-type work function layer 254e.

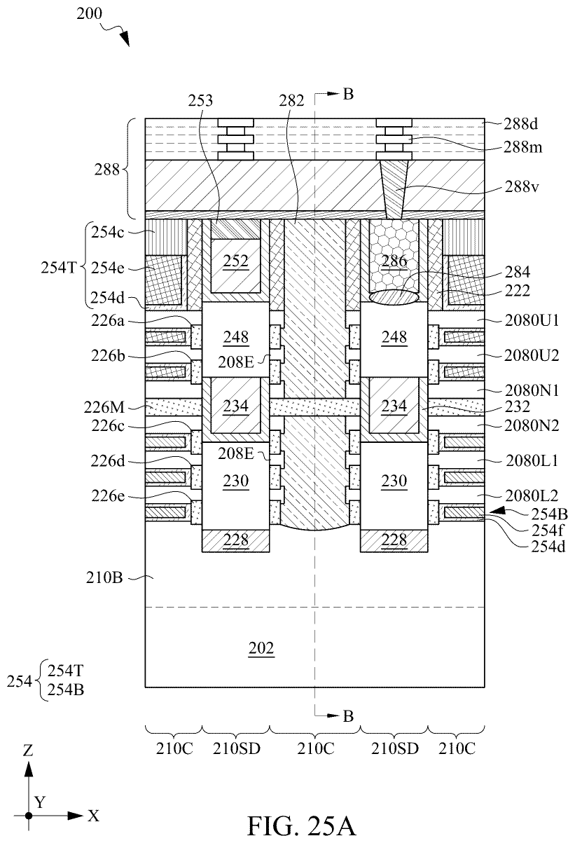

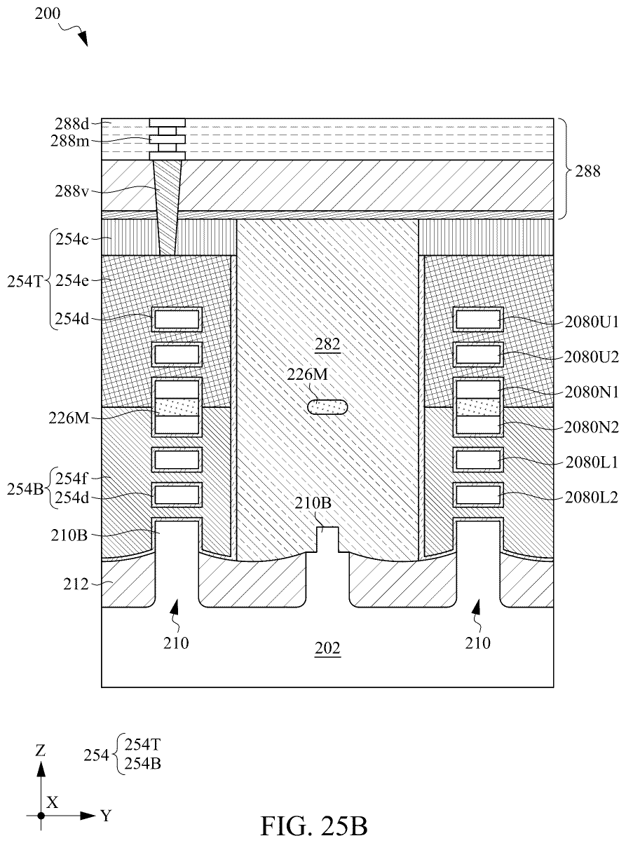

Referring to FIGS. 2 and 25A-25B, method 100 includes a block 140 where further processes are performed to form frontside multi-layer interconnect (MLI) structure 288 on the frontside of the workpiece 200. FIG. 25A depicts a cross-sectional view of the workpiece 200 in the X-Z plane, and FIG. 25B depicts a cross-sectional view of the workpiece 200 in the Y-Z plane, which is taken along cutline B-B shown in FIG. 25A. The frontside MLI 288 may include various interconnect features, such as vias 258v and conductive lines 258m, disposed in dielectric layers 258d, such as etch-stop layers and ILD layers. In some embodiments, the vias are vertical interconnect features configured to interconnect device-level contacts, such as source/drain contact 286 formed over the top source/drain features 248. The source/drain contact 286 extends through the top ILD layer 252 to electrically couple to the top source/drain feature 248. An electrical conductivity of the source/drain contact 286 is greater than an electrical conductivity of the top source/drain feature 248. Prior to the formation of the source/drain contact, a metal silicide layer 284 may be formed over the top source/drain feature 248. The metal silicide layer 284 may have a curved profile.

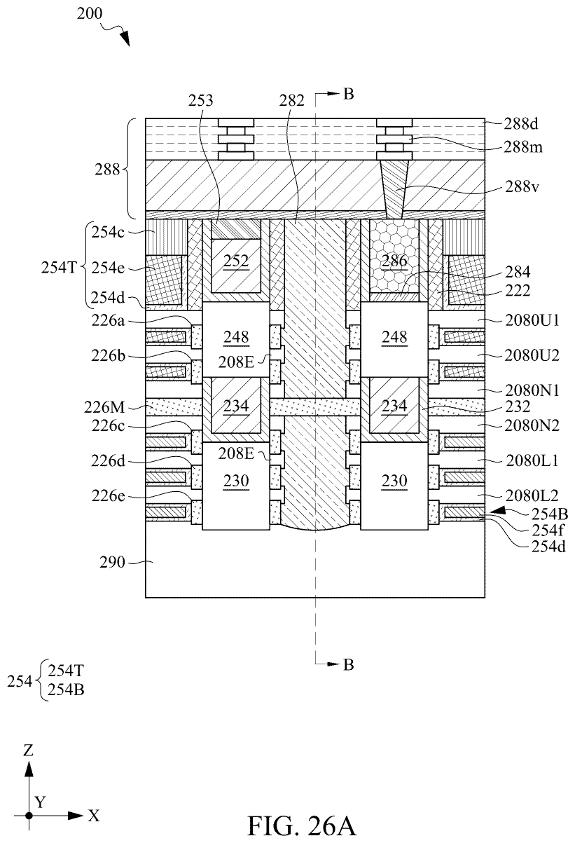

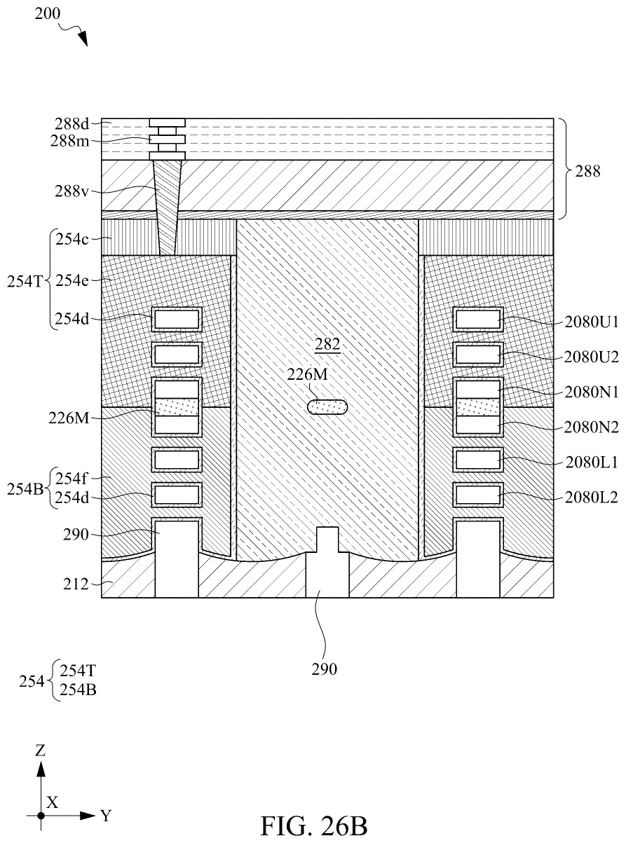

Referring to FIGS. 2 and 26A-26B, method 100 includes a block 142 where the workpiece 200 is thinned down from its backside and the fin-shaped base 210B is replaced with a backside dielectric layer 290. FIG. 26A depicts a cross-sectional view of the workpiece 200 in the X-Z plane, and FIG. 26B depicts a cross-sectional view of the workpiece 200 in the Y-Z plane, which is taken along cutline B-B shown in FIG. 26A. In some embodiments, operations at block 142 thin down the workpiece 200 from the backside of the workpiece 200 until the fin-shape bases 210B and the isolation feature 212 are exposed from the backside of the workpiece 200. The thinning process may include a mechanical grinding process and/or a chemical thinning process. A substantial amount of substrate material may be first removed from the substrate 202 during a mechanical grinding process. Afterwards, a chemical thinning process may apply an etching chemical to the backside of the substrate 202 to further thin down the substrate 202. In the illustrated embodiments, the isolation feature 212 may function as the thinning stop layer, such that the thinning process stops at the bottom surface of the isolation feature 212.

Subsequently, operations at block 142 selectively etch the fin-shape bases 210B to form a backside trench and deposit a backside dielectric layer 290 in the backside trench. The etching process is tuned to be selective to the semiconductor material (e.g., Si) in the fin-shape bases 210B and with no (or minimal) etching to the backside dielectric features. In the illustrated embodiment shown in FIG. 22A, the leakage blocking layer 228 is also removed. The backside trench exposes bottom surfaces of the CPODE feature 282, the gate dielectric layer 254d, bottom source/drain features 230, and bottommost inner spacers 226e. Operations at block 142 then deposit the backside dielectric layer 290 with one or more dielectric materials in the backside trench. In some embodiments, the backside dielectric layer 290 may include SiOCN, SiOC, SiCN, SiO2, SiC, ZrSi, other suitable material(s), or combinations thereof. In some embodiments, the backside dielectric layer 290 may include metal oxide or metal nitride, such as La₂O₃, Al₂O₃, ZnO, ZrN, Zr₂Al₃O₉, TiO₂, TaO₂, ZrO₂, HfO₂, Si₃N₄, Y₂O₃, AlON, TaCN, other suitable material(s), or combinations thereof. The backside dielectric layer 290 may be formed by PE-CVD, F-CVD or other suitable methods. The backside dielectric layer 290 is in direct contact with the bottom surfaces of the CPODE feature 282, the gate dielectric layer 254d, bottom source/drain features 230, and bottommost inner spacers 226e. After the deposition of the backside dielectric layer 290, the backside of the workpiece 200 is planarized by a planarization process, such as a CMP, to expose the bottom surface of the isolation feature 212.

In the illustrated embodiment, the backside dielectric layer 290 and the isolation feature 212 include different dielectric materials. In some embodiments, the backside dielectric layer 290 and the CPODE feature 282 include different dielectric materials. In furtherance of some embodiments, the backside dielectric layer 290, the middle dielectric layer 226M, and the CPODE feature 282 include dielectric material compositions different from each other. In furtherance of some embodiments, the backside dielectric layer 290 and the middle dielectric layer 226M include the same dielectric material, but different from the CPODE feature 282. In furtherance of some embodiments, the backside dielectric layer 290, the middle dielectric layer 226M, and the CPODE feature 282 include the same dielectric material composition, though the interfaces between these three dielectric features remain discernible.

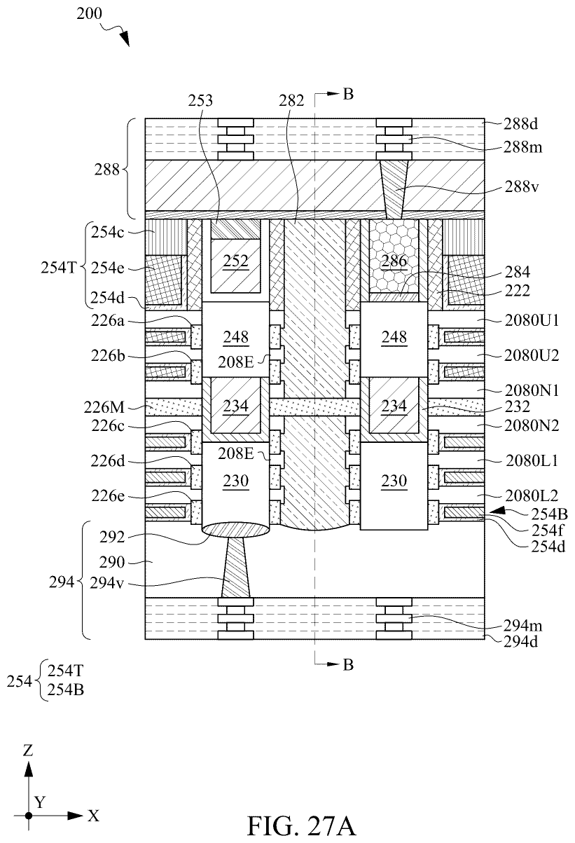

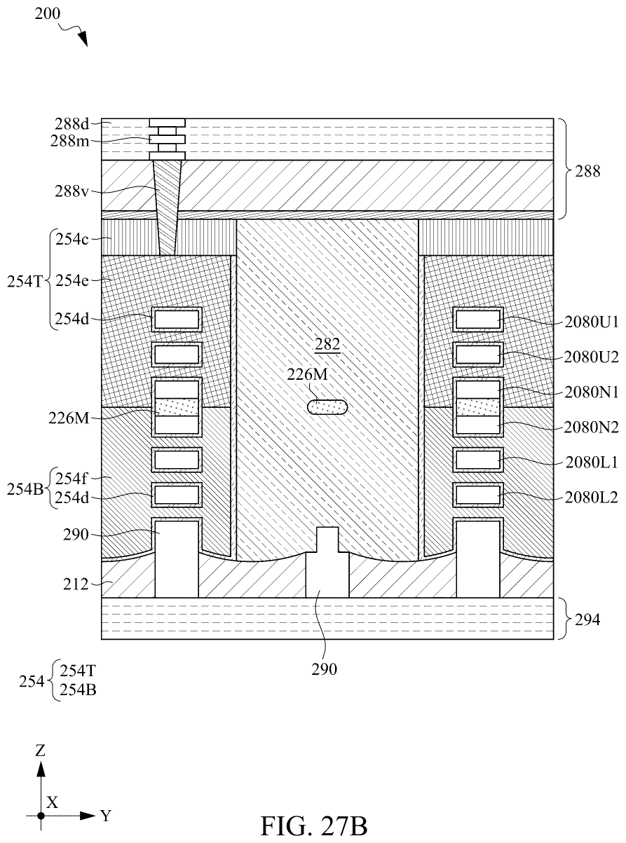

Referring to FIGS. 2 and 27A-27B, method 100 includes a block 144 where further processes are performed to form backside multi-layer interconnect (MLI) structure 294 on the backside of the workpiece 200. FIG. 27A depicts a cross-sectional view of the workpiece 200 in the X-Z plane, and FIG. 27B depicts a cross-sectional view of the workpiece 200 in the Y-Z plane, which is taken along cutline B-B shown in FIG. 27A. The backside MLI 294 may include various interconnect features, such as backside vias 294v and backside conductive lines 294m, disposed in backside dielectric layers 294d. In some embodiments, the backside vias are vertical interconnect features configured to interconnect backside conductive lines 294m and the bottom source/drain features 230. Prior to the formation of the backside vias 294v, a backside metal silicide layer 292 may be formed under the bottom surface of the bottom source/drain features 230. The backside metal silicide layer 292 may have a curved profile. Other processes may be further performed.

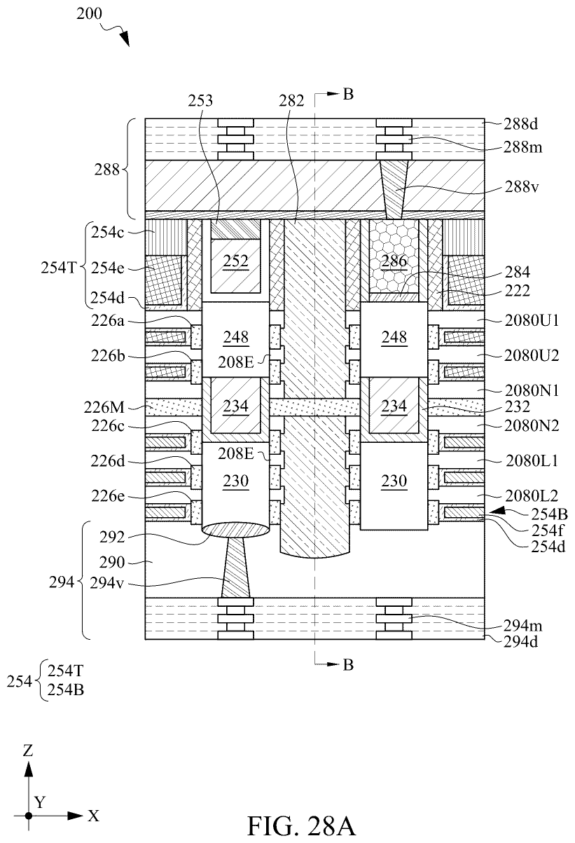

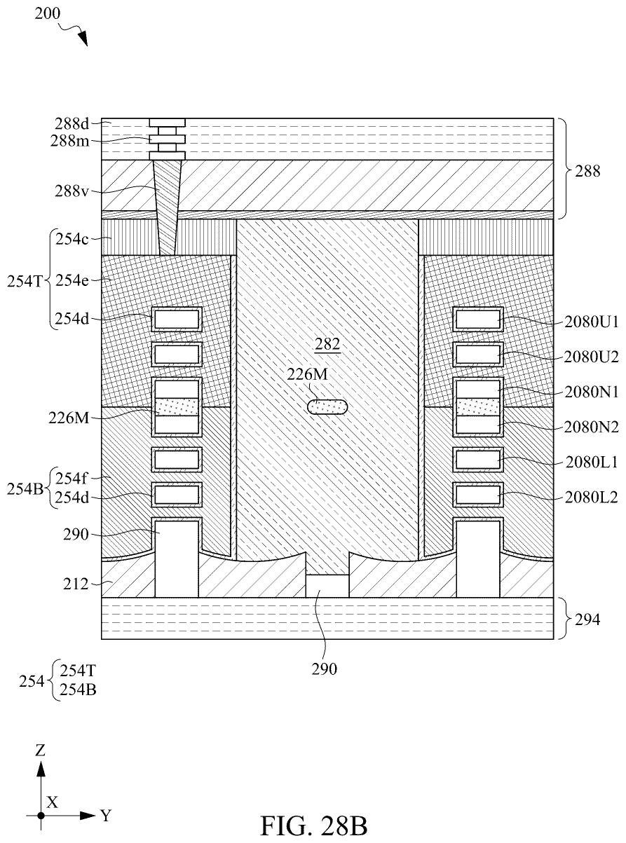

As discussed above with reference to FIGS. 23A and 23B, the bottom portion of the CPODE feature 282 may extend downward below the top surface of the isolation feature 212. FIGS. 28A and 28B illustrate such an alternative embodiment at the conclusion of block 144. FIG. 28A depicts a cross-sectional view of the workpiece 200 in the X-Z plane, and FIG. 28B depicts a cross-sectional view of the workpiece 200 in the Y-Z plane, which is taken along cutline B-B shown in FIG. 28A. The interface between the bottom surface of the CPODE feature 282 and the backside dielectric layer 290 may be positioned below the top surface of the isolation feature 212.

Although not intended to be limiting, one or more embodiments of the present disclosure provide several advantages for a semiconductor device and its formation. For example, the present disclosure provides an isolation structure disposed between two complementary field-effect transistors (C-FETs) to achieve electrical isolation. Each C-FET includes top and bottom source/drain features, with a dielectric feature vertically stacked between them. The dielectric feature may include a contact etch stop layer (CESL) and a bottom interlayer dielectric (ILD) layer. A middle dielectric layer connects the dielectric features of the two C-FETs, and the isolation structure wraps around this middle dielectric layer. Forming the isolation structure with the middle dielectric layer enclosed within helps preserve the integrity of adjacent dielectric and semiconductive features during manufacturing operations, thereby enhancing the overall reliability of the semiconductor device.

In one exemplary aspect, the present disclosure is directed to a method. The method includes receiving a workpiece. The workpiece includes a substrate, a fin-shaped structure extending lengthwise along a first direction over the substrate, the fin-shaped structure comprising a fin-shaped base, a bottom semiconductor stack over the fin-shaped base, a middle dielectric layer over the bottom semiconductor stack, and a top semiconductor stack over the middle dielectric layer. Each of the top and bottom semiconductor stacks includes channel layers interleaved by sacrificial layers. The workpiece also includes an isolation feature disposed over the substrate, a top surface of the isolation feature being non-planar when viewed along the first direction, a dielectric constant of the isolation feature between about 3 and about 5, and a dummy gate stack disposed over the fin-shaped structure and the isolation feature, the dummy gate stack extending lengthwise along a second direction different from the first direction. The method also includes recessing a portion of the dummy gate stack to form a trench, the trench exposing the fin-shaped structure, removing the sacrificial layers in the top and bottom semiconductor stacks from the trench, removing the channel layers in the top and bottom semiconductor stacks from the trench, and depositing a dielectric feature in the trench, the dielectric feature wrapping around the middle dielectric layer. In some embodiments the removing of the sacrificial layers includes applying a first isotropic etching process. In some embodiments, the removing of the channel layers includes applying a second isotropic etching process different from the first isotropic etching process. In some embodiments, the recessing of the portion of the dummy gate stack includes applying an anisotropic etching process. In some embodiments, the dielectric feature includes a dielectric liner and a dielectric layer over the dielectric liner. The dielectric liner interfaces and wraps around the middle dielectric layer. In some embodiments, the dielectric feature and the middle dielectric layer include different material compositions. In some embodiments, the method further includes etching the fin-shaped base to form a backside trench and depositing a backside dielectric layer in the backside trench. In some embodiments, a top portion of the backside dielectric layer is embedded in the dielectric feature. In some embodiments, the method further includes after the depositing of the dielectric feature, replacing the dummy gate stack with a gate structure, the gate structure including a gate dielectric layer deposited on sidewalls of the dielectric feature. In some embodiments, the gate structure includes a bottom gate electrode layer and a top gate electrode layer over the bottom gate electrode layer, the top and bottom gate electrode layers include different material compositions, and an interface between the top and bottom gate electrode layers is vertically positioned between top and bottom surfaces of the middle dielectric layer.

In another exemplary aspect, the present disclosure is directed to a method. The method includes forming a fin-shaped structure protruding from a substrate and extending lengthwise along a first direction, the fin-shaped structure including a plurality of channel layers interleaved by a plurality of sacrificial layers, forming a dummy gate stack over a first region of the fin-shaped structure and extending lengthwise along a second direction different from the first direction, depositing gate spacers on sidewalls of the dummy gate stack, recessing a second region of the fin-shaped structure to form a first source/drain trench and a third region of the fin-shaped structure to form a second source/drain trench, replacing one of the sacrificial layers with a middle dielectric layer, depositing a first bottom source/drain feature in the first source/drain trench, a first dielectric layer over the first bottom source/drain feature, and a first top source/drain feature over the first dielectric layer, depositing a second bottom source/drain feature in the second source/drain trench, a second dielectric layer over the second bottom source/drain feature, and a second top source/drain feature over the second dielectric layer, wherein the middle dielectric layer connects the first dielectric layer and the second dielectric layer, removing the dummy gate stack to form a trench between opposing sidewalls of the gate spacers, removing the sacrificial layers from the trench to release the channel layers, removing the channel layers from the trench to release the middle dielectric layer, depositing a dielectric feature in the trench, wherein the dielectric feature wraps around the middle dielectric layer, depositing a top dielectric layer over the second top source/drain feature, forming a metal silicide layer over the second top source/drain feature, the metal silicide layer comprising a curved profile, and forming a source/drain contact extending through the top dielectric layer to electrically couple to the second top source/drain feature by way of the metal silicide layer. An electrical conductivity of the source/drain contact is greater than an electrical conductivity of the second top source/drain feature. In some embodiments, along the first direction, the middle dielectric layer protrudes out of sidewalls of the dielectric feature. In some embodiments, the removing of the sacrificial layers includes a first isotropic etching process, and the removing of the channel layers includes a second isotropic etching process different from the first isotropic etching process. In some embodiments, the removing of the dummy gate stack includes an anisotropic etching process. In some embodiments, the removing of the channel layers reduces a width and a height of a base portion of the fin-shaped structure. In some embodiments, the method further includes replacing the base portion of the fin-shaped structure with a backside dielectric layer. In some embodiments, the one of the sacrificial layers replaced by the middle dielectric layer includes a material composition different from other ones of the sacrificial layers.

In yet another exemplary aspect, the present disclosure is directed to a semiconductor device. The semiconductor device includes a lower source/drain feature, a first plurality of nanostructures coupled to the lower source/drain feature, a first gate structure wrapping around each of the first plurality of nanostructures, a lower contact etch stop layer (CESL), and a lower interlayer dielectric (ILD) layer over the lower source/drain feature. A dielectric constant of the lower CESL is greater than a dielectric constant of the lower ILD layer. The semiconductor device also includes an upper source/drain feature over the lower CESL and the lower ILD layer, an upper CESL and an upper ILD layer over the upper source/drain feature. A dielectric constant of the upper CESL is greater than a dielectric constant of the upper ILD layer. The semiconductor device also includes a second plurality of nanostructures coupled to the upper source/drain feature, and a second gate structure wrapping around each of the second plurality of nanostructures. The second gate structure includes a gate dielectric layer and a gate electrode layer over the gate dielectric layer. The semiconductor device also includes a gate spacer extending along a sidewall of the second gate structure. A dielectric constant of the gate dielectric layer is greater than a dielectric constant of the gate spacer. The semiconductor device also includes a dielectric nanostructure extending horizontally from a sidewall of the lower CESL, and an isolation structure wraps around the dielectric nanostructure. The isolation structure interfaces sidewalls of the first and second gate structures. In some embodiments, the dielectric nanostructure and the isolation structure include different material compositions. In some embodiments, the semiconductor device further includes a fin-shaped dielectric feature partially embedded in a bottom portion of the isolation structure.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a workpiece comprising:
a substrate,
a fin-shaped structure extending lengthwise along a first direction over the substrate, the fin-shaped structure comprising a fin-shaped base, a bottom semiconductor stack over the fin-shaped base, a middle dielectric layer over the bottom semiconductor stack, and a top semiconductor stack over the middle dielectric layer, each of the top and bottom semiconductor stacks including channel layers interleaved by sacrificial layers,
an isolation feature disposed over the substrate, a top surface of the isolation feature being non-planar when viewed along the first direction, a dielectric constant of the isolation feature between about 3 and about 5, and
a dummy gate stack disposed over the fin-shaped structure and the isolation feature, the dummy gate stack extending lengthwise along a second direction different from the first direction;
recessing a portion of the dummy gate stack to form a trench, the trench exposing the fin-shaped structure;
removing the sacrificial layers in the top and bottom semiconductor stacks from the trench;
removing the channel layers in the top and bottom semiconductor stacks from the trench; and
depositing a dielectric feature in the trench, the dielectric feature wrapping around the middle dielectric layer.

2. The method of claim 1, wherein the removing of the sacrificial layers includes applying a first isotropic etching process.

3. The method of claim 2, wherein the removing of the channel layers includes applying a second isotropic etching process different from the first isotropic etching process.

4. The method of claim 3, wherein the recessing of the portion of the dummy gate stack includes applying an anisotropic etching process.

5. The method of claim 1, wherein the dielectric feature includes a dielectric liner and a dielectric layer over the dielectric liner, wherein the dielectric liner interfaces and wraps around the middle dielectric layer.

6. The method of claim 1, wherein the dielectric feature and the middle dielectric layer include different material compositions.

7. The method of claim 1, further comprising:
etching the fin-shaped base to form a backside trench; and
depositing a backside dielectric layer in the backside trench.

8. The method of claim 7, wherein a top portion of the backside dielectric layer is embedded in the dielectric feature.

9. The method of claim 1, further comprising:
after the depositing of the dielectric feature, replacing the dummy gate stack with a gate structure, the gate structure including a gate dielectric layer deposited on sidewalls of the dielectric feature.

10. The method of claim 9, wherein the gate structure includes a bottom gate electrode layer and a top gate electrode layer over the bottom gate electrode layer, the top and bottom gate electrode layers include different material compositions, and an interface between the top and bottom gate electrode layers is vertically positioned between top and bottom surfaces of the middle dielectric layer.

11. A method, comprising:
forming a fin-shaped structure protruding from a substrate and extending lengthwise along a first direction, the fin-shaped structure including a plurality of channel layers interleaved by a plurality of sacrificial layers;
forming a dummy gate stack over a first region of the fin-shaped structure and extending lengthwise along a second direction different from the first direction;
depositing gate spacers on sidewalls of the dummy gate stack;
recessing a second region of the fin-shaped structure to form a first source/drain trench and a third region of the fin-shaped structure to form a second source/drain trench;
replacing one of the sacrificial layers with a middle dielectric layer;
depositing a first bottom source/drain feature in the first source/drain trench, a first dielectric layer over the first bottom source/drain feature, and a first top source/drain feature over the first dielectric layer;
depositing a second bottom source/drain feature in the second source/drain trench, a second dielectric layer over the second bottom source/drain feature, and a second top source/drain feature over the second dielectric layer, wherein the middle dielectric layer connects the first dielectric layer and the second dielectric layer;
removing the dummy gate stack to form a trench between opposing sidewalls of the gate spacers;
removing the sacrificial layers from the trench to release the channel layers;
removing the channel layers from the trench to release the middle dielectric layer;
depositing a dielectric feature in the trench, wherein the dielectric feature wraps around the middle dielectric layer;
depositing a top dielectric layer over the second top source/drain feature;
forming a metal silicide layer over the second top source/drain feature, wherein the metal silicide layer comprises a curved profile; and
forming a source/drain contact extending through the top dielectric layer to electrically couple to the second top source/drain feature by way of the metal silicide layer, wherein an electrical conductivity of the source/drain contact is greater than an electrical conductivity of the second top source/drain feature.

12. The method of claim 11, wherein along the first direction, the middle dielectric layer protrudes out of sidewalls of the dielectric feature.

13. The method of claim 11, wherein the removing of the sacrificial layers includes a first isotropic etching process, the removing of the channel layers includes a second isotropic etching process different from the first isotropic etching process.

14. The method of claim 13, wherein the removing of the dummy gate stack includes an anisotropic etching process.

15. The method of claim 11, wherein the removing of the channel layers reduces a width and a height of a base portion of the fin-shaped structure.

16. The method of claim 15, further comprising:
replacing the base portion of the fin-shaped structure with a backside dielectric layer.

17. The method of claim 11, wherein the one of the sacrificial layers replaced by the middle dielectric layer includes a material composition different from other ones of the sacrificial layers.

18. A semiconductor device, comprising:
a lower source/drain feature;
a first plurality of nanostructures coupled to the lower source/drain feature;
a first gate structure wrapping around each of the first plurality of nanostructures;
a lower contact etch stop layer (CESL) and a lower interlayer dielectric (ILD) layer over the lower source/drain feature, wherein a dielectric constant of the lower CESL is greater than a dielectric constant of the lower ILD layer;
an upper source/drain feature over the lower CESL and the lower ILD layer;
an upper CESL and an upper ILD layer over the upper source/drain feature, wherein a dielectric constant of the upper CESL is greater than a dielectric constant of the upper ILD layer;
a second plurality of nanostructures coupled to the upper source/drain feature;
a second gate structure wrapping around each of the second plurality of nanostructures, wherein the second gate structure includes a gate dielectric layer and a gate electrode layer over the gate dielectric layer;
a gate spacer extending along a sidewall of the second gate structure, wherein a dielectric constant of the gate dielectric layer is greater than a dielectric constant of the gate spacer;
a dielectric nanostructure extending horizontally from a sidewall of the lower CESL; and
an isolation structure wraps around the dielectric nanostructure, wherein the isolation structure interfaces sidewalls of the first and second gate structures.

19. The semiconductor device of claim 18, wherein the dielectric nanostructure and the isolation structure include different material compositions.

20. The semiconductor device of claim 18, further comprising:
a fin-shaped dielectric feature partially embedded in a bottom portion of the isolation structure.
